(19) United States
(12) Patent Application Publication
(10) Pub. No.: US 2026/0280165 A1
(43) Pub. Date: Sep. 17, 2026

(54) SEMICONDUCTOR DEVICE, SEMICONDUCTOR MODULE, POWER CONVERSION UNIT, AND METHOD FOR MANUFACTURING SEMICONDUCTOR DEVICE

(71) Applicant: ROHM CO., LTD., Kyoto-shi (JP)

(72) Inventors: Tomohiro YASUNISHI, Kyoto-shi (JP); Takayuki ISHIHARA, Kyoto-shi (JP); Hideki SAWADA, Kyoto-shi (JP)

(21) Appl. No.: 19/665,701

(22) Filed: May 1, 2026

Related U.S. Application Data
(63) Continuation of application No. PCT/JP2024/038453, filed on Oct. 29, 2024.

(30) Foreign Application Priority Data
Nov. 9, 2023 (JP) 2023-191322

(51) Int. Cl. H01R 12/71; H01R 13/04; H05K 1/14; H05K 3/36; H10W 90/10

(52) U.S. Cl. CPC H01R 12/718; H01R 13/04; H05K 1/145; H05K 3/368; H10W 90/10; H05K 2201/066; H05K 2201/10318

(57) ABSTRACT

A semiconductor device includes a semiconductor element, a plurality of connecting parts each being conductive, a sealing part that covers the semiconductor element and a portion of each of the connecting parts, a plurality of signal terminals each inserted into one of the connecting parts, and a holding part. The signal terminals protrude from the sealing part toward a first side in a thickness direction of the sealing part. The holding part covers a portion of each signal terminal. In one example, the signal terminals are collectively held and inserted into the connecting parts.

### TECHNICAL FIELD

The present disclosure relates to a semiconductor device, a semiconductor module, a power conversion unit, and a method for manufacturing a semiconductor device.

### BACKGROUND ART

Various configurations of semiconductor devices incorporating semiconductor elements have been proposed. JP-A-2020-17702 discloses an example of a conventional semiconductor device. The semiconductor device disclosed in JP-A-2020-17702 includes a semiconductor chip, a sealing resin, and a plurality of press-fit terminals. The sealing resin covers the semiconductor chip. The press-fit terminals protrude from the upper surface of the sealing resin and extend upward. The semiconductor device including the press-fit terminals is used in combination with a circuit board. During assembly of the semiconductor device and a circuit board, the press-fit terminals are press-fitted into through-holes formed in the circuit board. In this process, the press-fit terminals and the through-holes of the circuit board need to be aligned with high accuracy. However, when a plurality of press-fit terminals are provided, positional deviations of the terminals tend to occur, which may interfere with the assembly of the semiconductor device with the circuit board.

### BRIEF DESCRIPTION OF THE DRAWINGS

FIG. 1 is a perspective view of a power conversion unit according to a first embodiment.

FIG. 2 is a perspective view of FIG. 1, with a wiring board omitted.

FIG. 3 is a plan view of the power conversion unit according to the first embodiment.

FIG. 4 is a plan view of FIG. 3, with the wiring board omitted.

FIG. 5 is a front view of the power conversion unit according to the first embodiment.

FIG. 6 is a bottom view of the power conversion unit according to the first embodiment.

FIG. 7 is a left-side view of the power conversion unit according to the first embodiment.

FIG. 8 is a right-side view of the power conversion unit according to the first embodiment.

FIG. 9 is a sectional view taken along line IX-IX in FIG. 4.

FIG. 10 is a sectional view taken along line X-X in FIG. 4.

FIG. 11 is a sectional view taken along line XI-XI in FIG. 4.

FIG. 12 is a sectional view taken along line XII-XII in FIG. 4.

FIG. 13 is a sectional view taken along line XIII-XIII in FIG. 4.

FIG. 14 is an enlarged partial sectional view of the power conversion unit according to the first embodiment.

FIG. 15 is a perspective view of a semiconductor device for the power conversion unit according to the first embodiment.

FIG. 16 is a plan view of the semiconductor device for the power conversion unit according to the first embodiment.

FIG. 17 is a plan view of FIG. 16, in which a holding part is omitted and a sealing part is indicated by an imaginary line.

FIG. 18 is a plan view of FIG. 17, in which the holding part, the sealing part, and a second conductive member are omitted.

FIG. 19 is a front view of the semiconductor device for the power conversion unit according to the first embodiment.

FIG. 20 is a bottom view of the semiconductor device for the power conversion unit according to the first embodiment.

FIG. 21 is a sectional view taken along line XXI-XXI in FIG. 17.

FIG. 22 is an enlarged partial sectional view of FIG. 21.

FIG. 23 is an enlarged partial sectional view of FIG. 21.

FIG. 24 is a sectional view taken along line XXIV-XXIV in FIG. 17.

FIG. 25 is a sectional view taken along line XXV-XXV in FIG. 17.

FIG. 26 is a sectional view taken along line XXVI-XXVI in FIG. 17.

FIG. 27 is a sectional view taken along line XXVII-XXVII in FIG. 17.

FIG. 28 is an enlarged partial sectional view of FIG. 9.

FIG. 29 is a sectional view illustrating a step of a method for manufacturing a semiconductor device according to the first embodiment.

FIG. 30 is a sectional view illustrating a step subsequent to FIG. 29.

FIG. 31 is a sectional view illustrating a step subsequent to FIG. 30.

FIG. 32 is a schematic view of a vehicle including the power conversion unit according to the first embodiment.

FIG. 33 is an enlarged partial sectional view of a power conversion unit according to a first variation of the first embodiment, corresponding to the section shown in FIG. 11.

FIG. 34 is a sectional view illustrating a step of an assembly procedure of the power conversion unit according to the first variation of the first embodiment.

FIG. 35 is a sectional view illustrating a step subsequent to FIG. 34.

FIG. 36 is a sectional view illustrating a step subsequent to FIG. 35.

FIG. 37 is a plan view of a power conversion unit according to a second embodiment.

FIG. 38 is a front view of the power conversion unit according to the second embodiment.

FIG. 39 is an enlarged partial sectional view of FIG. 37.

FIG. 40 is an enlarged partial sectional view of FIG. 38.

FIG. 41 is an enlarged partial sectional view of an interconnect wiring shown in FIG. 40.

### DETAILED DESCRIPTION OF EMBODIMENTS

The following specifically describes preferred embodiments of the present disclosure with reference to the drawings.

In the following description, like reference numerals are used to denote the same or similar elements, and redundant descriptions are omitted. In the present disclosure, the terms such as “first”, “second”, “third”, and so on are used only as labels and are not intended to imply any order of the items to which they refer.

In the present disclosure, the expressions “An object A is formed in an object B”, and “An object A is formed on an object B” imply the situations where, unless otherwise specifically noted, “the object A is formed directly in or on the object B”, and “the object A is formed in or on the object B, with something else interposed between the object A and the object B.” Likewise, the expressions “An object A is arranged in an object B”, and “An object A is arranged on an object B” imply the situations where, unless otherwise specifically noted, “the object A is arranged directly in or on the object B”, and “the object A is arranged in or on the object B, with something else interposed between the object A and the object B”. Likewise, the expression “An object A is positioned on an object B” implies the situations where, unless otherwise specifically noted, “the object A is positioned on the object B, in contact with the object B”, and “the object A is positioned on the object B, with something else interposed between the object A and the object B.” The expression “An object A overlaps with an object B as viewed in a certain direction” implies the situations where, unless otherwise specifically noted, “the object A overlaps with the entirety of the object B”, and “the object A overlaps with a portion of the object B.” The expression “An object A (or the material of an object A) contains a material C” implies the situations where “the object A consists of the material C” and “the object A is made primarily of the material C”. In the present disclosure, the expression “A surface A faces a direction B (one side or the other side in that direction) is not limited to the situation where the surface A forms an angle of 90° with the direction B, but includes the situation where the surface A is inclined with respect to the direction B.

### First Embodiment

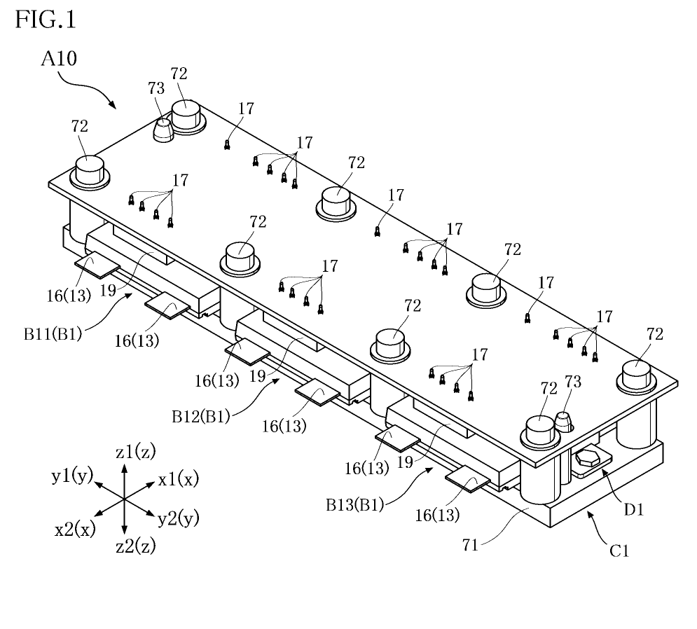

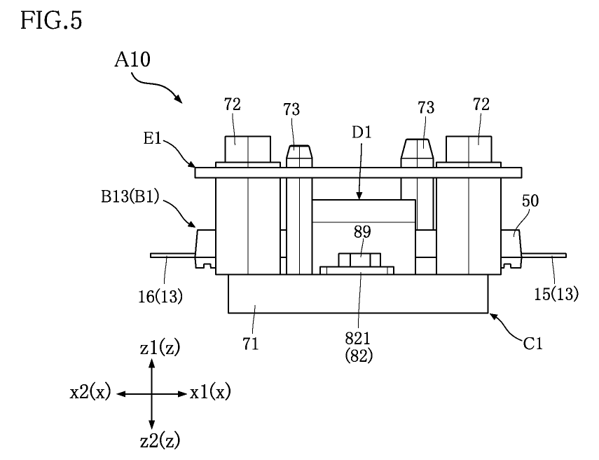

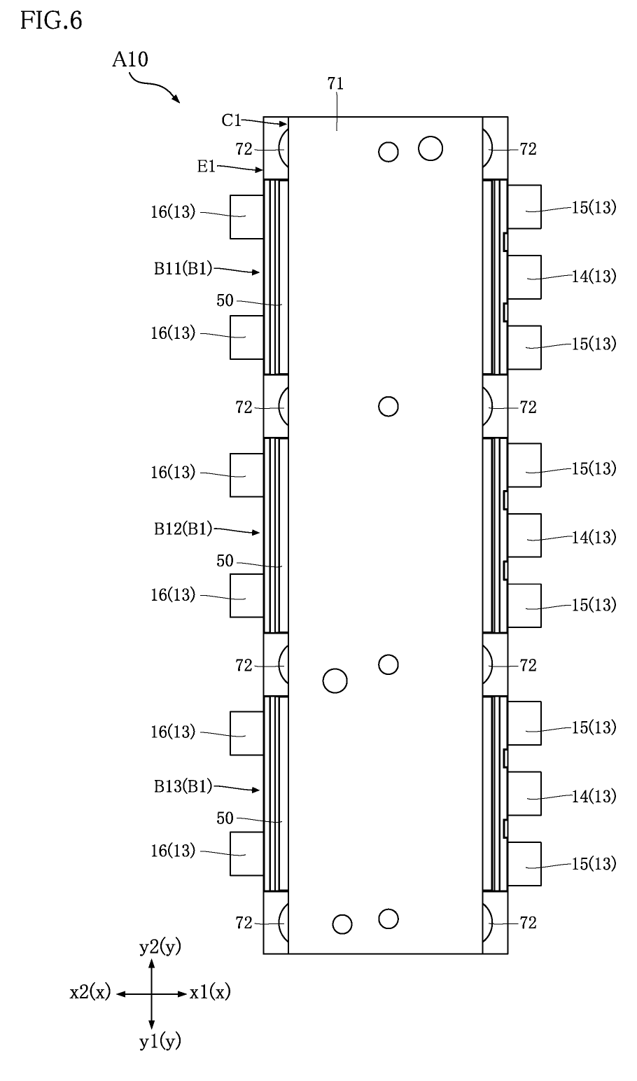

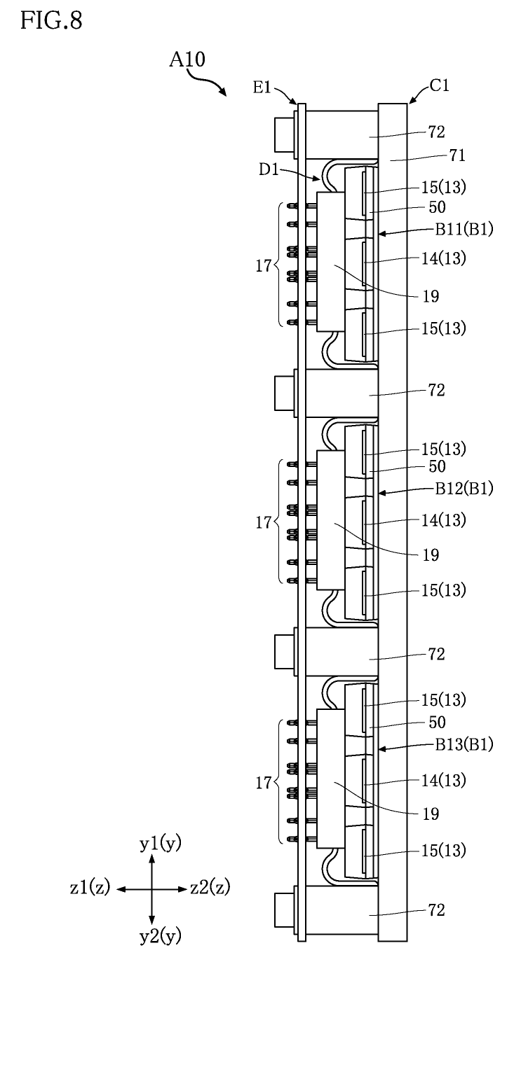

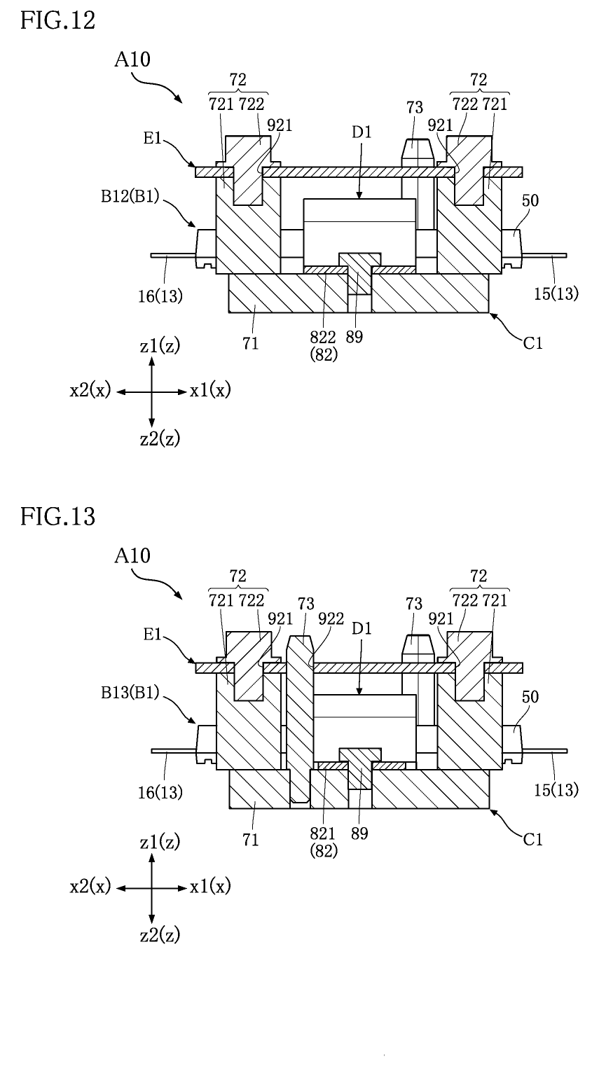

FIGS. 1 to 14 show a power conversion unit A10 according to a first embodiment. The power conversion unit A10 includes a plurality of semiconductor devices B1, one heat sink C1, one attachment member D1, and one wiring board E1. For example, the power conversion unit A10 is used for an inverter that drives a three-phase AC motor.

In the following description, reference is made to three mutually perpendicular directions: the thickness direction z, the first direction x, and the second direction y. The thickness direction z corresponds to the thickness direction of the power conversion unit A10. In the following description, “in plan view” refers to a view as seen in the thickness direction z. The first direction x is perpendicular to the thickness direction z. The second direction y is perpendicular to the thickness direction z and the first direction x. Terms such as “top”, “bottom”, “above”, “below”, “upper surface”, “lower surface”, and so on are used to describe the relative positions of elements or components along the thickness direction z and not necessarily describe their positions with respect to the direction of gravity.

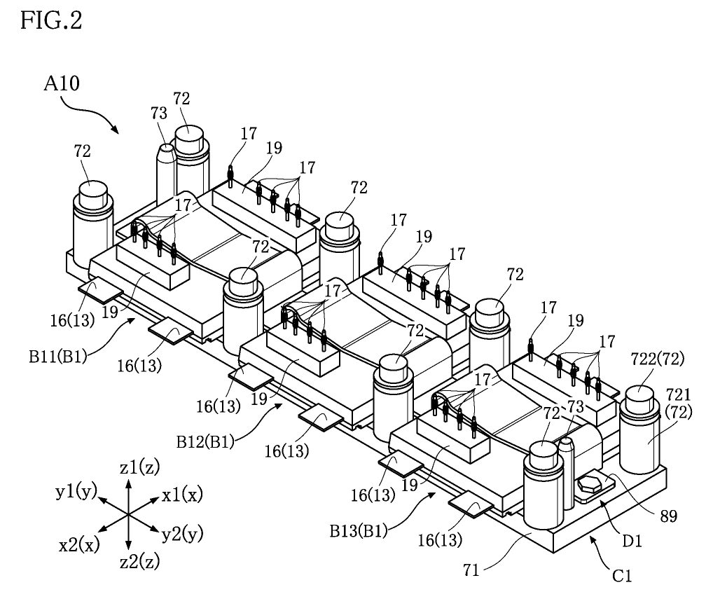

As shown in FIGS. 2, 4, 7, and 8, the plurality of semiconductor devices B1 are arranged along the second direction y. Each semiconductor device B1 includes a plurality of semiconductor elements 21. As will be understood from the configuration described in detail below, the semiconductor elements 21 are switching elements, such as MOSFETs (metal-oxide-semiconductor field-effect transistors) or IGBTs (insulated gate bipolar transistors), and each semiconductor device B1 forms a half-bridge switching circuit. As shown in FIGS. 1 to 9, each semiconductor device B1 includes a plurality of power terminals 13, a plurality of signal terminals 17, a holding part 19, and a sealing part 50. In each semiconductor device B1, the semiconductor elements 21 are covered with the sealing part 50. The power terminals 13 protrude from a side surface (a first side surface 531 described later) of the sealing part 50 in the first direction x. The signal terminals 17 protrude from the upper surface (a top surface 51 described later) of the sealing part 50 in the thickness direction z.

In the illustrated example, the power conversion unit A10 includes three semiconductor devices B1 but may alternatively include two or four or more semiconductor devices B1. In the following description, the three semiconductor devices B1 may be differentiated as a first device B11, a second device B12, and a third device B13 as necessary. Among the plurality of semiconductor devices B1, the first device B11 is positioned outermost on the y1 side in the second direction y, and the third device B13 is positioned outermost on the y2 side in the second direction y. The second device B12 is positioned between the first device B11 and the third device B13 in the second direction y.

The heat sink C1 supports the semiconductor devices B1. Most of the heat sink C1 is positioned below (on the z2 side with respect to) the semiconductor devices B1 in the thickness direction z. The heat sink C1 faces the lower surface (a bottom surface 52 described later) of the sealing part 50 of each semiconductor device B1. The heat sink C1 contains aluminum, for example. However, the material of the heat sink C1 is not limited to aluminum and may be another metal or a resin material (preferably one having high thermal conductivity). The heat sink C1 includes a main body 71, a plurality of pedestals 72, and a plurality of positioning portions 73.

The main body 71 is a plate. The semiconductor devices B1 are mounted on the main body 71. As shown in FIGS. 2, 4, 7, and 8, the semiconductor devices B1 are arranged along the second direction y on the main body 71. The main body 71 faces the lower surface (the bottom surface 52 described later) of the sealing part 50 of each semiconductor device B1. The main body 71 is in contact with the semiconductor devices B1. For example, the main body 71 is rectangular in plan view.

As shown in FIGS. 2, 5, and 7 to 13, each pedestal 72 protrudes upward from the main body 71 in the thickness direction z. In the illustrated example, the pedestals 72 are formed integrally with the main body 71 but may alternatively be separate components attached to the main body 71.

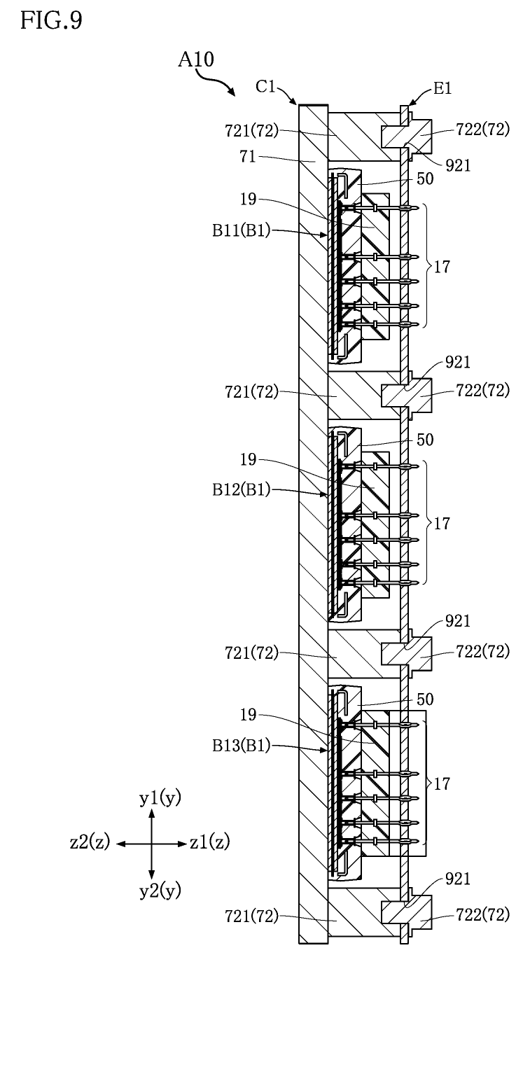

As shown in FIGS. 9 to 13, each pedestal 72 includes a first part 721 and a second part 722. The first part 721 is positioned between the wiring board E1 and the main body 71 in the thickness direction z. The dimension of the first part 721 in the thickness direction z is greater than the dimension of the sealing part 50 of each semiconductor device B1 in the thickness direction z. The second part 722 is positioned on the first part 721. The wiring board E1 is sandwiched between the first part 721 and the second part 722. With this configuration, the wiring board E1 is held a predetermined distance apart from the upper surface of the main body 71.

In the illustrated example, the first part 721 includes an internally threaded recess, and the second part 722 includes an externally threaded projection. The second part 722 is fastened to the first part 721 by inserting the external thread (the projection) of the second part 722 into the internal thread (the recess) of the first part 721. Each pedestal 72 may have a different configuration, provided that the first part 721 and the second part 722 fit together. For example, the second part 722 may be press-fit into the first part 721. The first part 721 may include a projection, and the second part 722 may include a recess.

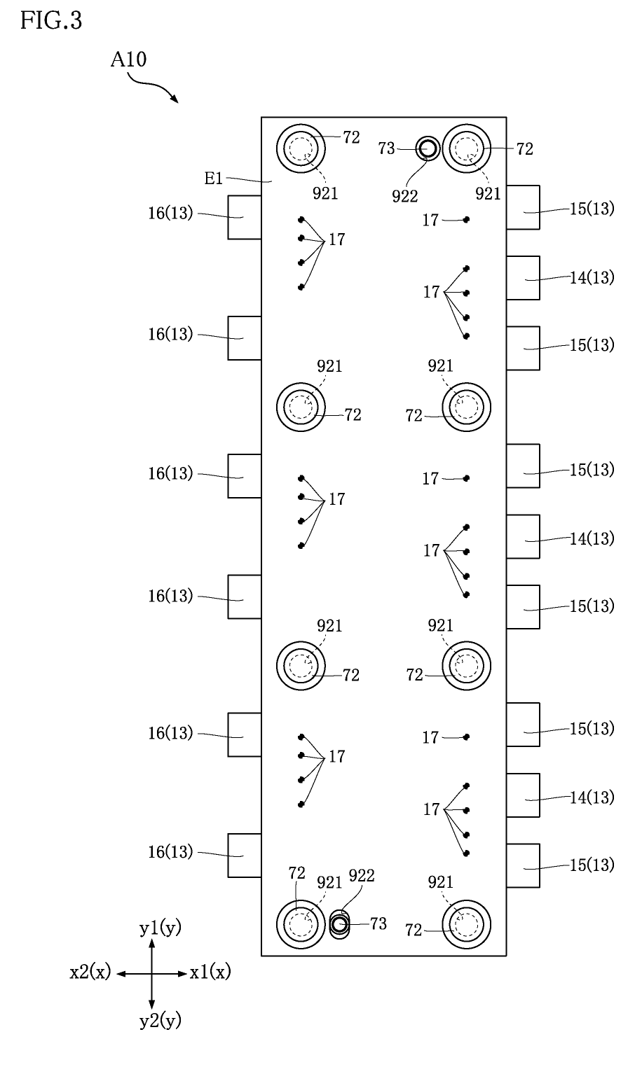

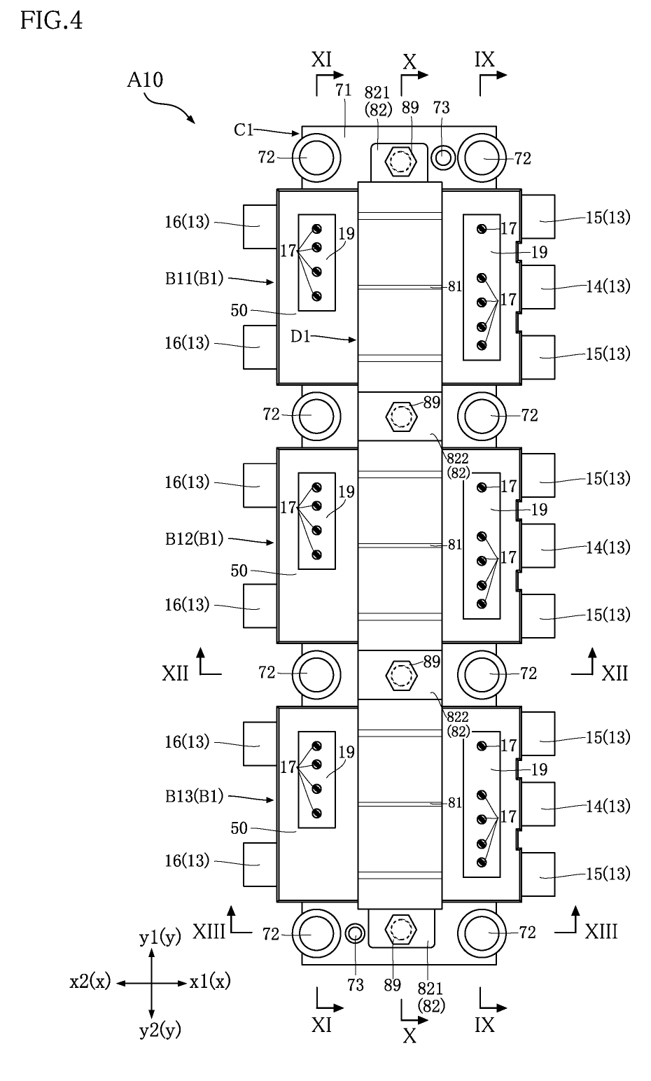

As shown in FIGS. 2 and 13, each positioning portion 73 protrudes upward from the main body 71 in the thickness direction z. In the illustrated example (see FIG. 13, for example), each positioning portion 73 is a separate component attached to the main body 71. In a different example, each positioning portion 73 may be formed integrally with the main body 71. In the example shown in FIG. 13, each positioning portion 73 is press-fitted into a through-hole formed in the main body 71. Each positioning portion 73 has a columnar shape with a tapered end on the z1 side in the thickness direction z. In the illustrated example, each positioning portion 73 has a smaller diameter than each pedestal 72 in plan view. As shown in FIGS. 3 and 4, the positioning portions 73 include one positioned on the y1 side in the second direction y with respect to the first device B11, and one positioned on the y2 in the second direction y with respect to the third device B13.

The attachment member D1 holds the semiconductor devices B1 against the heat sink C1. The attachment member D1 may be a leaf spring. The attachment member D1 presses the semiconductor devices B1 against the heat sink C1 by elastic force. The material of the attachment member D1 is not particularly limited and may be copper, iron, titanium or an alloys of such a metal (including stainless steel, for example). As shown in FIGS. 4, and 7 to 13, the attachment member D1 includes a plurality of pressing portions 81 and a plurality of fixed portions 82.

The pressing portions 81 are provided for the respective semiconductor devices B1. Each pressing portion 81 is in contact with the sealing part 50 (the top surface 51) of the corresponding semiconductor device B1. Each pressing portion 81 presses the contacting semiconductor device B1 against the main body 71 of the heat sink C1.

The fixed portions 82 are secured to the heat sink C1 or to the main body 71 of the heat sink C1 in the present embodiment. Each fixed portion 82 may be a flat-plate that is parallel to the x-y plane. Each fixed portion 82 is formed with a through-hole. The through-hole is for insertion of a fastener 89 (a hexagon head bolt in the illustrated example). The fixed portion 82 is secured to the main body 71 by the fastener 89.

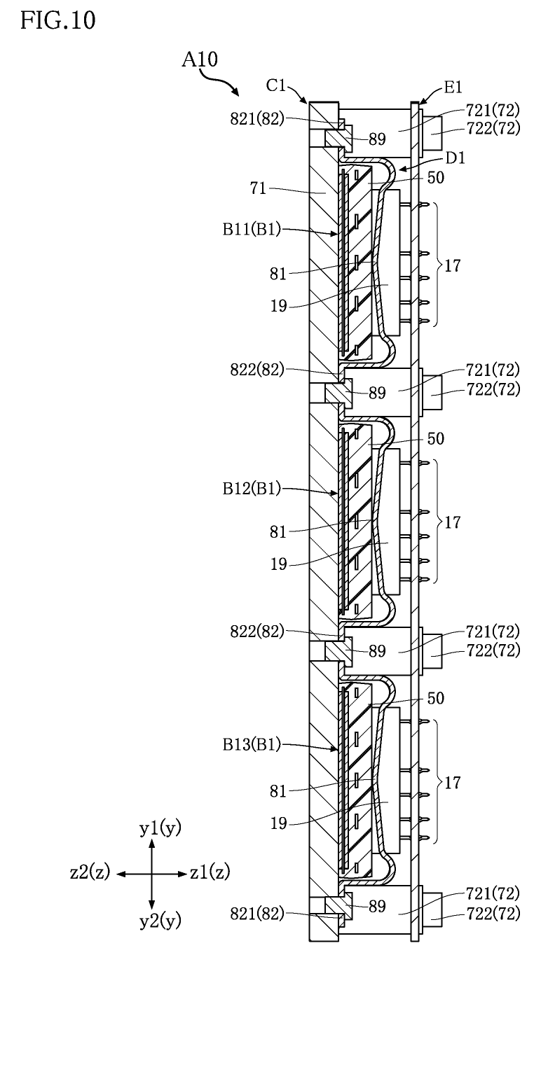

The fixed portions 82 include a plurality of end-position portions 821 and a plurality of intermediate-position portions 822. In the power conversion unit A10, the fixed portions 82 include a pair of end-position portions 821 and two intermediate-position portions 822. As shown in FIGS. 4 and 10, one of the end-position portions 821 is positioned on the y1 side in the second direction y with respect to the first device B11, and the other end-position portion 821 is positioned on the y2 side in the second direction y with respect to the third device B13. One of the two intermediate-position portions 822 is positioned between the first device B11 and the second device B12, and the other intermediate-position portion 822 is positioned between the second device B12 and the third device B13.

In the example shown in FIG. 4, the width (the dimension in the first direction x) of each end-position portion 821 is narrower than the width (the dimension in the first direction x) of each pressing portion 81 as well as the width (the dimension in the first direction x) of each intermediate-position portion 822. This configuration prevents interference between the attachment member D1 (the end-position portions 821) and the positioning portions 73. In a different example, the pressing portions 81 and the intermediate-position portions 822 may have the same width as the end-position portions 821. In this case, the attachment member D1 has a rectangular shape (band shape) in plan view. In another example, the intermediate-position portions 822 may have the same width as the end-position portions 821.

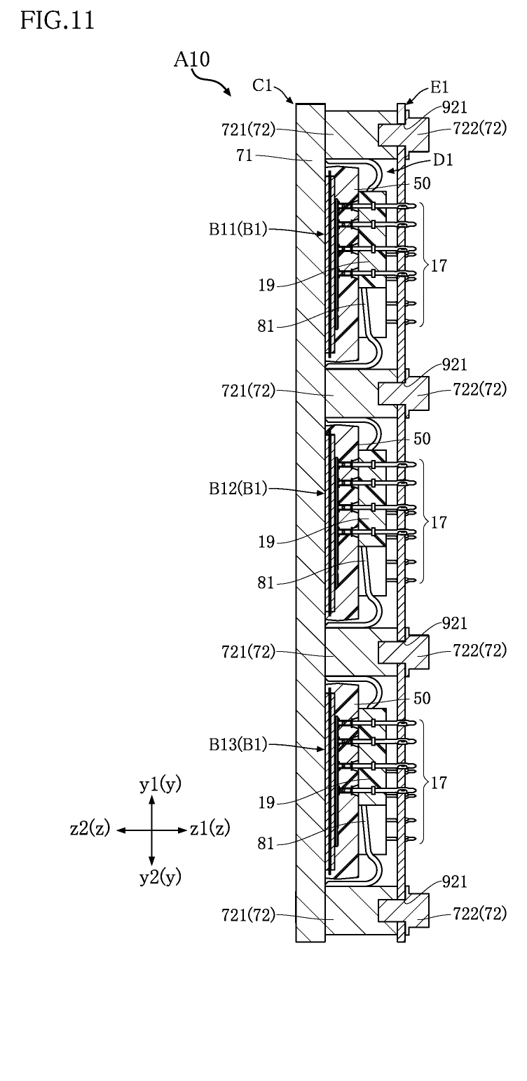

As shown in FIGS. 1, 3, 7, and 8, the wiring board E1 is provided for commonly for the plurality of semiconductor device B1. In a different example, a plurality of wiring boards E1 may be provided for the respective semiconductor devices B1. As can be understood from FIGS. 9 and 11, the wiring board E1 receives the signal terminals 17 of the semiconductor devices B1. The wiring board E1 is electrically connected to the signal terminals 17. The wiring board E1 includes a drive circuit for driving the semiconductor elements 21 of the semiconductor devices B1. When the semiconductor elements 21 are MOSFETs or IGBTs, the wiring board E1 serves as a gate driver. The wiring board E1 is positioned above (the z1 side) the sealing parts 50 of the semiconductor devices B1 in the thickness direction z. The wiring board E1 faces the upper surface (the top surface 51) of the sealing part 50 of each semiconductor device B1. The wiring board E1 is positioned on the side opposite the main body 71 of the heat sink C1 with respect to the plurality of semiconductor devices B1. In plan view, the wiring board E1 overlaps with the sealing parts 50 of the semiconductor devices B1. The wiring board E1 is supported by the pedestals 72 at a predetermined distance from the upper surface (the top surface 51) of the sealing part 50 of each semiconductor device B1 in the thickness direction z. The wiring board E1 is an example of the control board of the present disclosure.

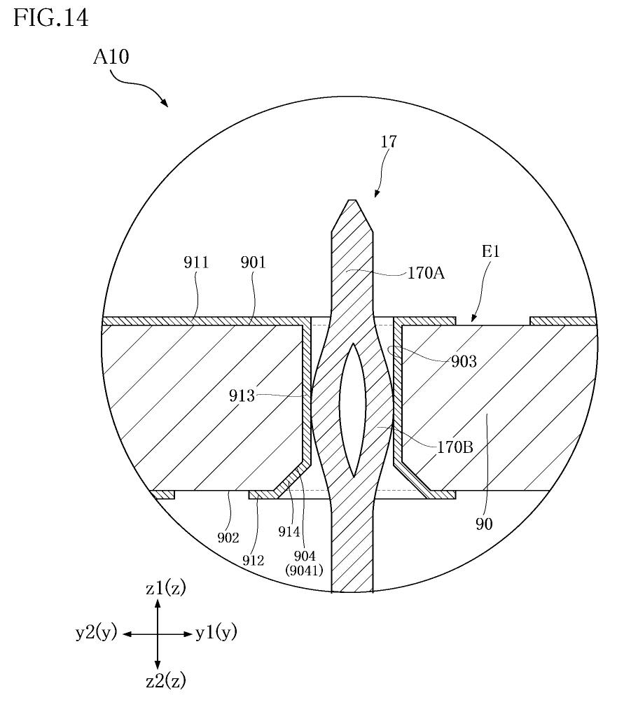

As shown in FIG. 14, the wiring board E1 includes a base 90, a first wiring 911, a second wiring 912, a third wiring 913, and a fourth wiring 914.

The base 90 includes a first surface 901 and a second surface 902. The first surface 901 is on the upper side (the z1 side) of the base 90 in the thickness direction z and faces the z1 side in the thickness direction z. The second surface 902 is on the lower side (the z2 side) of the base 90 in the thickness direction z and faces the z2 side in the thickness direction z. The base 90 includes a plurality of through-holes 903 extending in the thickness direction z. In the present embodiment, the base 90 includes a plurality of first recesses 904. Each first recess 904 is recessed from the inner surface of a through-hole 903 and the second surface 902. The first recesses 904 are provided for the respective through-holes 903. Each first recess 904 includes a portion that is inclined radially inward of the through-hole 903 toward the z1 side in the thickness direction z (a first portion 9041). In the present embodiment, the entire or substantially entire first recess 904 is inclined radially inward of the through-hole 903 toward the z1 side in the thickness direction z, forming a shape resembling a cone. The method of forming the first recess 904 is not particularly limited. For example, the first recess 904 may be formed by machining the base 90 from the z2 side in the thickness direction z, using a drill with a conical tip to remove material concentrically around the through-hole 903.

The first wiring 911 is disposed on the first surface 901 of the base 90. The second wiring 912 is disposed on the second surface 902. The third wiring 913 is disposed on the inner surface of the through-hole 903 and is connected to the first wiring 911. The fourth wiring 914 is disposed in the first recess 904. The fourth wiring 914 is connected to both the second wiring 912 and the third wiring 913. The first wiring 911 forms a conduction path that interconnects the second, fourth, and third wirings 912, 914, and 913 and a circuit formed on the wiring board E1. For example, the first wiring 911, the second wiring 912, the third wiring 913, and the fourth wiring 914 are formed by metal plating on the surface of the base 90. The composition of the metal plating includes copper (Cu). While the present embodiment shows the base 90 having the first recesses 904, the base 90 may alternatively have no first recesses 904. In this case, the second wiring 912 disposed on the second surface 902 is connected to the third wiring 913 disposed in the through-hole 903.

In each semiconductor device B1, the signal terminals 17 are inserted into the corresponding through-holes 903 in the wiring board E1. FIG. 14 shows a signal terminal 17 of a semiconductor device B1 inserted into the corresponding through-hole 903 in the base 90. All of the signal terminals 17 of each semiconductor device B1 are inserted into the corresponding through-holes 903 in the base 90 as shown in FIG. 14. The semiconductor device B1 and the wiring board E1 form a semiconductor module of the present disclosure.

As shown in FIG. 14, each signal terminal 17 includes a base portion 170A and a first bulging portion 170B. A portion of the base portion 170A on the z2 side in the thickness direction z is inserted into one of a plurality of sleeves 64 (described later) of the semiconductor device B1. The first bulging portion 170B is positioned on the z1 side in the thickness direction z with respect to the base portion 170A. The first bulging portion 170B is enlarged relative to the base portion 170A in a direction perpendicular to the thickness direction z.

As shown in FIG. 14, each signal terminal 17 is press-fitted into the corresponding through-hole 903 in the wiring board E1. Thus, the first bulging portion 170B of each signal terminal 17 inserted into the corresponding through-hole 903 contacts with the third wiring 913 in that through-hole 903. Thus, each signal terminal 17 is electrically connected to the wiring board E by being press-fitted into a through-hole 903 in the thickness direction z. The wiring board E1 is supported by the signal terminals 17 that are press-fitted into the corresponding through-holes 903. In a different configuration, each signal terminal 17 may consist only of a base portion 170A and include no first bulging portion 170B. In short, each signal terminal 17 may be a straight pin with no variation in diameter. In this case, each signal terminal 17 is inserted through a through-hole 903 and then soldered to the wiring board E1.

As shown in FIGS. 3, 9, and 11 to 13, the wiring board E1 is formed with a plurality of mounting holes 921 and a plurality of positioning holes 922.

As shown in FIGS. 3, 9, and 11 to 13, each mounting hole 921 receives a pedestal 72 (e.g., a second part 722). For example, each mounting hole 921 is a perfect circle in plan view. The diameter of each mounting hole 921 in plan view is smaller than that of each pedestal 72 (the first part 721 in particular) in plan view. Consequently, the wiring board E1 is held above (the z1 side) the first part 721 in the thickness direction z.

As shown in FIGS. 3 and 13, each positioning hole 922 receives a positioning portion 73. In the illustrated example, the wiring board E1 includes two positioning holes 922. One of the positioning holes 922 (the positioning hole 922 on the y1 side in the second direction y) is a perfect circle, whereas the other positioning hole 922 (the positioning hole 922 on the y2 side in the second direction y) is elongated. This facilitates positioning of the wiring board E1 relative to the heat sink C1. The elongated positioning hole 922 accommodates displacement between the heat sink C1 and the wiring board E1 due to manufacturing tolerances.

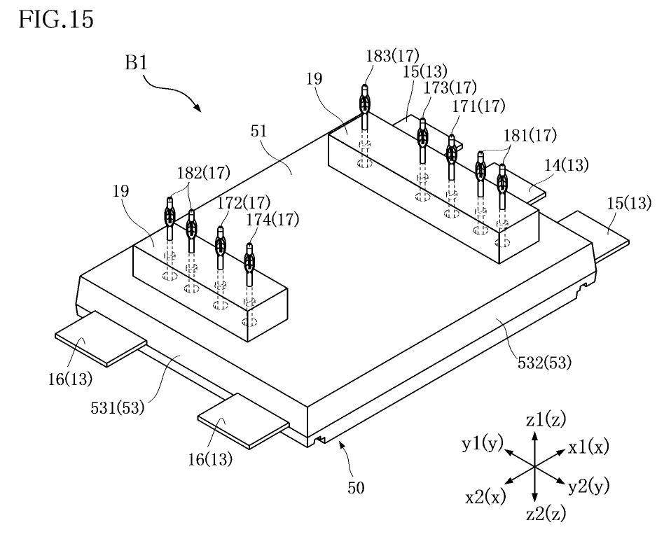

With reference to FIGS. 15 to 27, the following describes the configuration example of the semiconductor devices B1. FIGS. 15 to 27 are enlarged views of one of the semiconductor devices B1. The semiconductor devices B1 are all identical in structure. Unless otherwise specifically noted, the description of the semiconductor device B1 given below commonly applies to the first device B11, the second device B12, and the third device B13.

As shown in FIGS. 15 to 27, the semiconductor device B1 (each of the first device B11, the second device B12, and the third device B13) includes the plurality of power terminals 13, the plurality of signal terminals 17, the holding part 19, the plurality of semiconductor elements 21, and the sealing part 50 as described above. The semiconductor device B1 additionally includes a supporting substrate 11, a pair of thermistors 22, a conductive bonding layer 23, a first conductive member 31, a second conductive member 32, a plurality of wires, and a pair of control wirings 60. The power terminals 13 include a first power terminal 14, two second power terminals 15, and two third power terminals 16. The signal terminals 17 include a first signal terminal 171, a second signal terminal 172, a third signal terminal 173, a fourth signal terminal 174, a pair of fifth signal terminals 181, and a pair of sixth signal terminals 182. The wires include a plurality of first wires 41, a plurality of second wires 42, a plurality of third wires 43, and a fourth wire 44.

The semiconductor device B1 converts the DC power supply voltage applied to the first power terminal 14 and the two second power terminals 15 into AC power using the semiconductor elements 21. The AC power thus converted is output from the two third power terminals 16 to a load, such as a motor.

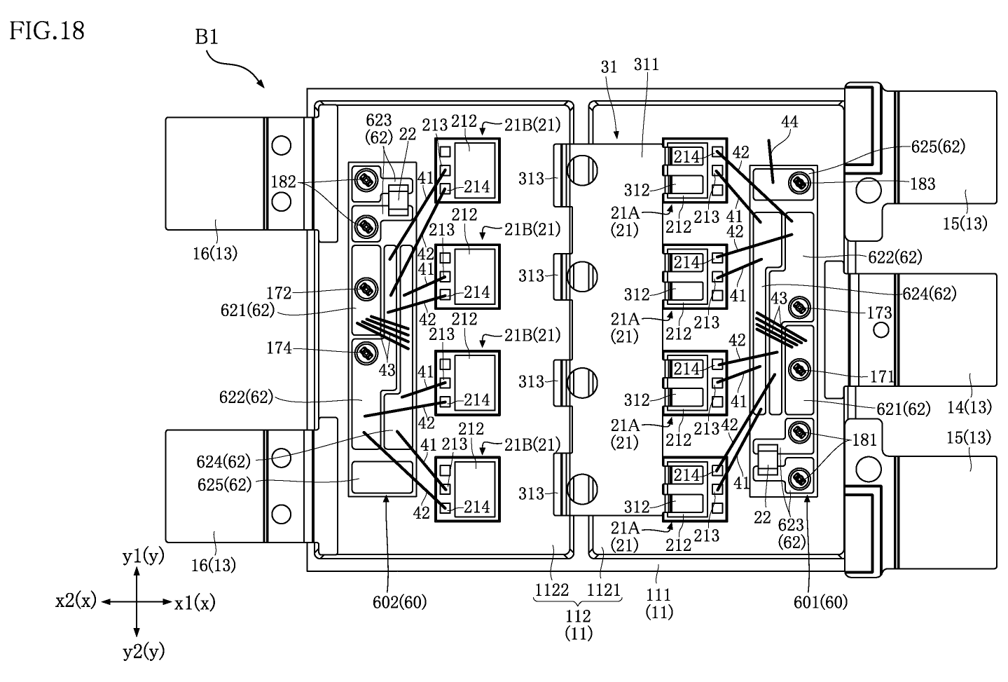

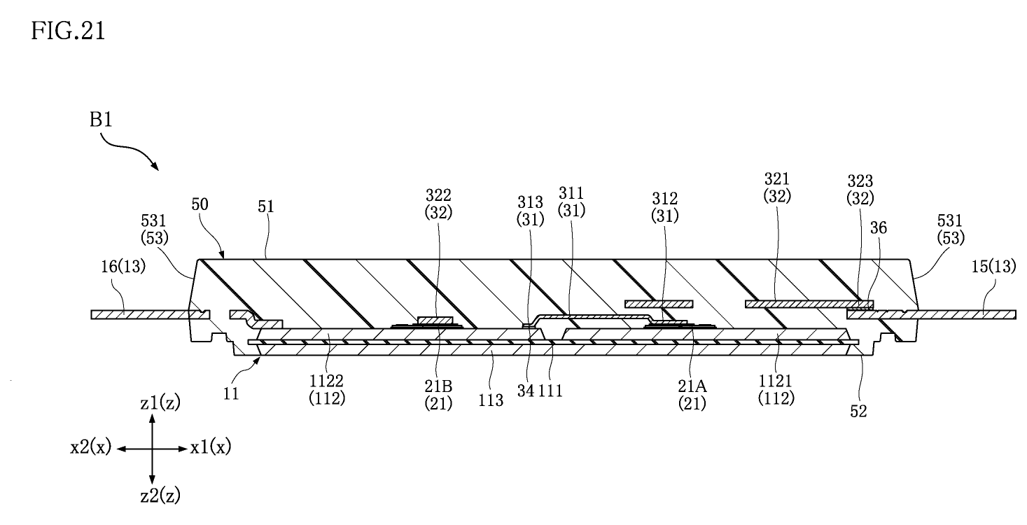

As shown in FIGS. 18 and 21, the supporting substrate 11 supports the semiconductor elements 21 in the thickness direction z. The supporting substrate 11 may be formed with a DBC (direct bonded copper) substrate. As shown in FIGS. 21 to 27, the supporting substrate 11 includes an insulating layer 111, a first wiring layer 112, and a second wiring layer 113. The supporting substrate 11 is covered with the sealing part 50, except over a portion of the second wiring layer 113.

As shown in FIGS. 21 to 27, the insulating layer 111 includes regions disposed between the first wiring layer 112 and the second wiring layer 113 in the thickness direction z. The insulating layer 111 is made of a material with relatively high thermal conductivity. For example, the insulating layer 111 is made of a ceramic material, such as one containing aluminum nitride (AlN). Alternatively, the insulating layer 111 may be formed from an insulating resin sheet rather than a ceramic material.

As shown in FIGS. 18, and 21 to 27, the first wiring layer 112 is positioned above (the z1 side) the insulating layer 111 in the thickness direction z. The composition of the first wiring layer 112 includes copper (Cu). As shown in FIG. 18, the first wiring layer 112 is surrounded by the peripheral edge of the insulating layer 111 in plan view. As shown in FIGS. 18, and 21 to 27, the first wiring layer 112 includes a first mounting section 1121 and a second mounting section 1122. The first mounting section 1121 and the second mounting section 1122 are rectangular in plan view. The first mounting section 1121 and the second mounting section 1122 are spaced apart from each other in the first direction x. The first mounting section 1121 is positioned on the x1 side in the first direction x with respect to the second mounting section 1122. Each semiconductor element 21 is bonded to either the first mounting section 1121 or the second mounting section 1122.

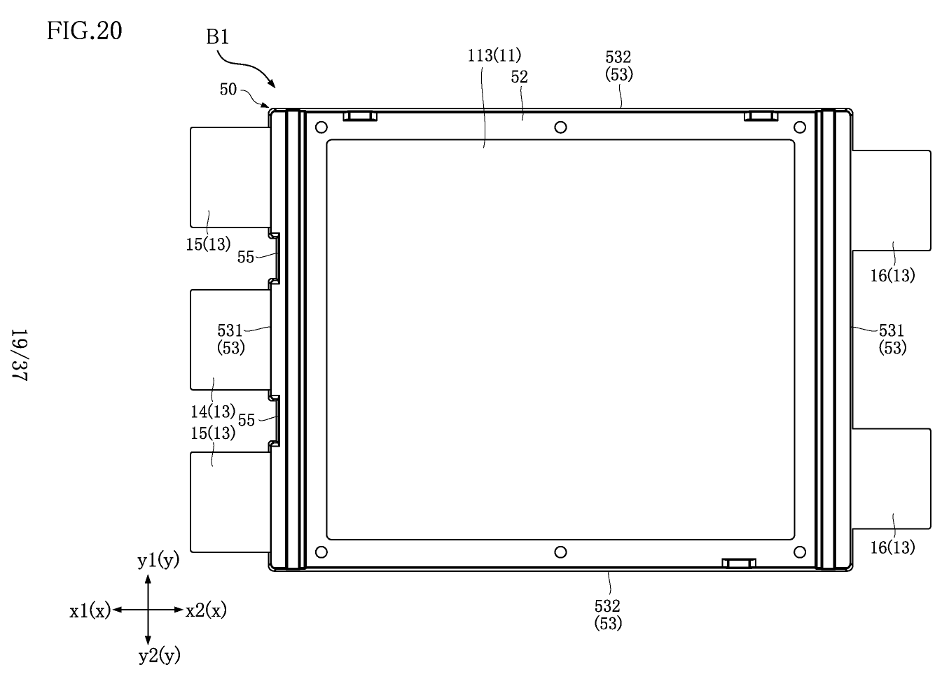

As shown in FIGS. 21 to 26, the second wiring layer 113 is positioned below (the z2 side) the insulating layer 111 in the thickness direction z. As shown in FIG. 20, the second wiring layer 113 is exposed from the sealing part 50. The lower surface (the surface facing the z2 side in the thickness direction z) of the second wiring layer 113 is the bottom surface of the supporting substrate 11. The lower surface of the second wiring layer 113 (the bottom surface of the supporting substrate 11) is in contact with the upper surface (the surface facing the z1 side in the thickness direction z) of the main body 71 of the heat sink C1. The composition of the second wiring layer 113 includes copper. The second wiring layer 113 is rectangular in plan view. The second wiring layer 113 is surrounded by the peripheral edge of the insulating layer 111 in plan view.

As shown in FIGS. 18 and 21, each semiconductor element 21 is mounted on either the first mounting section 1121 or the second mounting section 1122. In one example, the semiconductor elements 21 are MOSFETs. In other examples, the semiconductor elements 21 may be switching elements, such as IGBTs, or diodes. In the description of the semiconductor device B1, the semiconductor elements 21 are n-channel MOSFETs having a vertical structure. Each semiconductor element 21 includes a compound semiconductor substrate. The composition of the compound semiconductor substrate includes silicon carbide (SiC) or silicon (Si).

As shown in FIGS. 18 and 21, the semiconductor elements 21 of the semiconductor device B1 include a plurality of first elements 21A and a plurality of second elements 21B. The second elements 21B are identical in structure to the first elements 21A. As shown in FIGS. 18, 21, and 22, the first elements 21A are mounted on the first mounting section 1121. The first elements 21A are arranged along the second direction y. As shown in FIGS. 18, 21, and 23, the second elements 21B are mounted on the second mounting section 1122. The second elements 21B are arranged along the second direction y.

As shown in FIGS. 18, 22, and 23, each semiconductor elements 21 includes a first electrode 211, a second electrode 212, a third electrode 213, and two fourth electrodes 214.

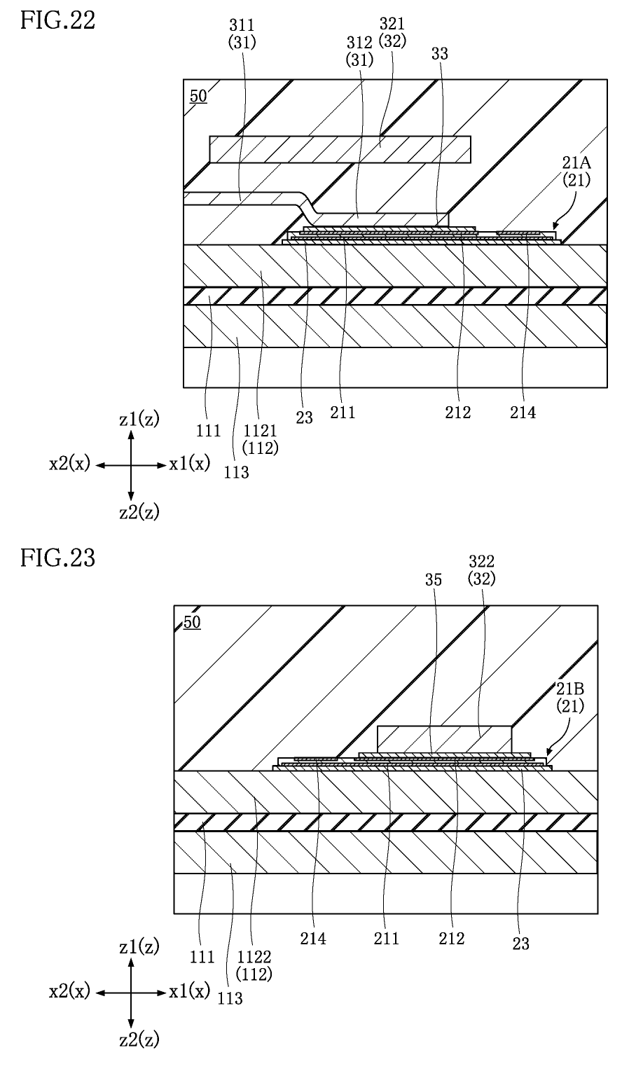

As shown in FIGS. 22 and 23, the first electrode 211 faces the first mounting section 1121 or the second mounting section 1122. The first electrode 211 carries the current corresponding to the power before conversion by the semiconductor element 21. That is, the first electrode 211 corresponds to the drain electrode of the semiconductor element 21.

As shown in FIGS. 22 and 23, the second electrode 212 is positioned on the side opposite the first electrode 211 in the thickness direction z. The second electrode 212 carries the current corresponding to the power after conversion by the semiconductor element 21. That is, the second electrode 212 corresponds to the source electrode of the semiconductor element 21.

As shown in FIG. 18, the third electrode 213 is positioned on the same side as the second electrode 212 in the thickness direction z. The third electrode 213 receives a drive signal (a gate voltage) for driving the semiconductor element 21. That is, the third electrode 213 corresponds to the gate electrode of the semiconductor element 21. As shown in FIG. 18, the third electrode 213 has a smaller area than the second electrode 212 in plan view.

As shown in FIGS. 18, 22, and 23, the two fourth electrodes 214 are positioned on the same side as the second electrode 212 in the thickness direction z and are next to the third electrode 213 in the first direction x. In the illustrated example, the two fourth electrodes 214 are arranged on either side of the third electrode 213 in the first direction x with the third electrode 213 positioned between them. Each of the fourth electrodes 214 is at the same potential as the second electrode 212. In contrast to the illustrated example, each semiconductor element 21 may include a single fourth electrode 214 or no fourth electrode 214.

As shown in FIGS. 22 and 23, the conductive bonding layer 23 is disposed between the first mounting section 1121 or the second mounting section 1122 and the first electrode 211 of a semiconductor element 21. In one example, the conductive bonding layer 23 is solder. In another example, the conductive bonding layer 23 may contain sintered metal particles. The first electrode 211 of each first element 21A is electrically bonded to the first mounting section 1121 via the conductive bonding layer 23. Thus, the first electrode 211 of each first element 21A is electrically connected to the first mounting section 1121. The first electrode 211 of each second element 21B is electrically bonded to the second mounting section 1122 via the conductive bonding layer 23. Thus, the first electrode 211 of each second element 21B is electrically connected to the second mounting section 1122.

Each power terminal 13 is electrically connected to the semiconductor elements 21. Each power terminal 13 carries the current corresponding to either the power before conversion by the semiconductor element 21 or the power after conversion by the semiconductor element 21. The power terminals 13 include a first power terminal 14, two second power terminals 15, and two third power terminals 16.

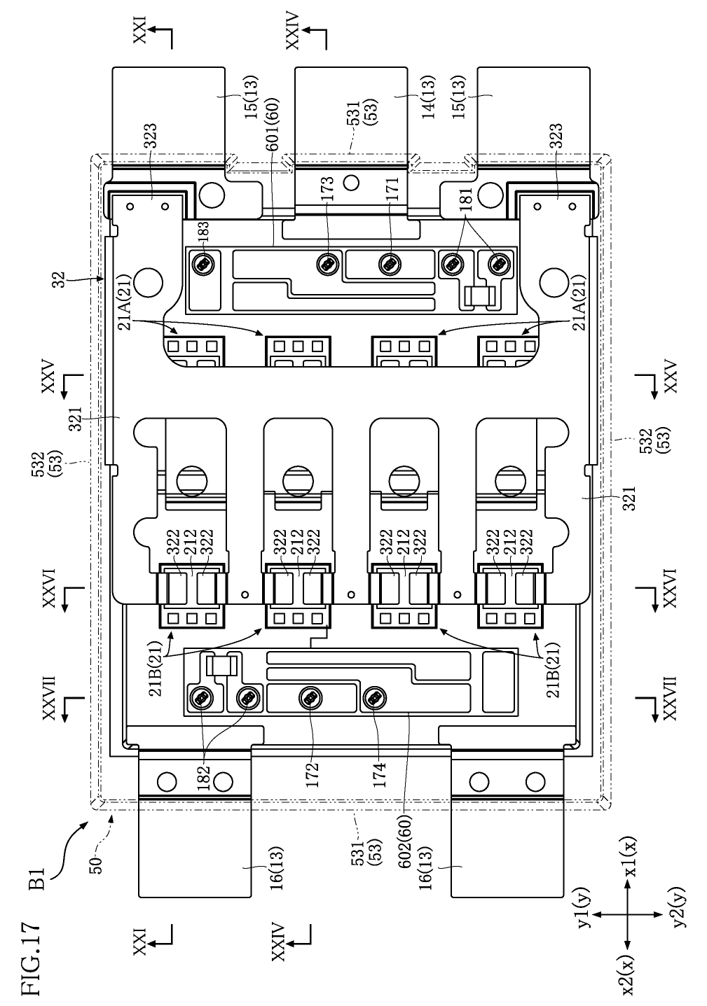

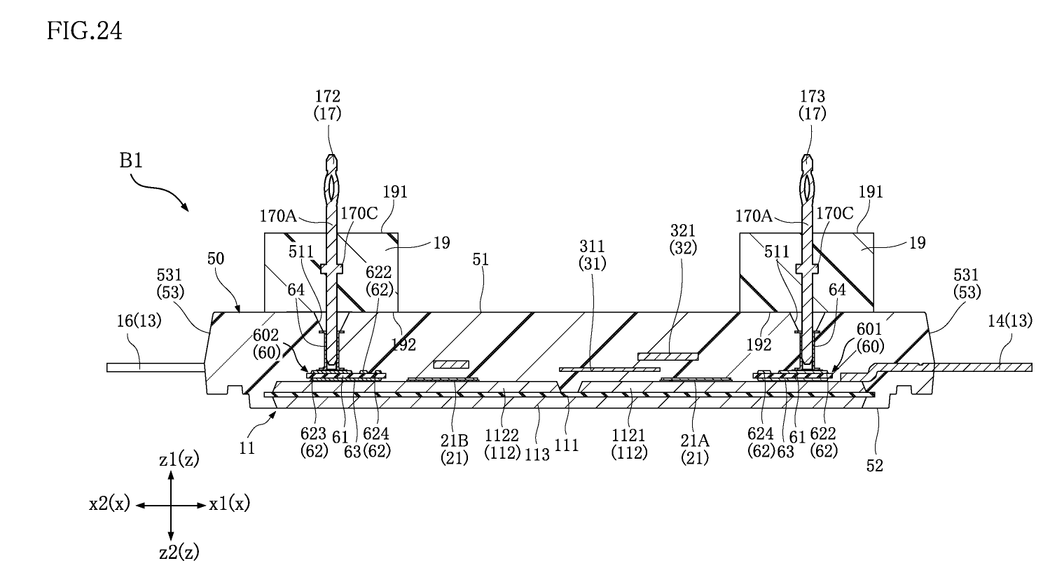

As shown in FIGS. 18 and 24, the first power terminal 14 is bonded to the first mounting section 1121. The type of bonding is not particularly limited. The bonding may be made by using a conductive bonding material (e.g., solder) not shown in the figures, by laser welding, or by crimping. The first power terminal 14 is electrically connected to the first electrodes 211 of the first elements 21A via the first mounting section 1121. The first power terminal 14 is a P terminal (positive terminal) to which the DC power supply voltage to be converted by the semiconductor device is applied. As shown in FIG. 18, the first power terminal 14 is positioned on the side opposite the second mounting section 1122 with the first mounting section 1121 between them in the first direction x. The first power terminal 14 extends from the first mounting section 1121 toward the first side (the x1 side) in the first direction x, protruding from the sealing part 50 toward the first side (the x1 side) in the first direction x. As shown in FIGS. 17 and 24, the first power terminal 14 includes a portion covered with the sealing part 50 and a portion exposed from the sealing part 50. The portion of the first power terminal 14 that is covered with the sealing part 50 is bonded to the first mounting section 1121. The portion of the first power terminal 14 that is exposed from the sealing part 50 is used as the P terminal of the semiconductor device B1 described above.

The two second power terminals 15 are bonded to the second conductive member 32. The two second power terminals 15 are electrically connected to the second electrodes 212 of the second elements 21B via the second conductive member 32. The two second power terminals 15 are N terminals (negative terminals) to which the DC power supply voltage to be converted by the semiconductor device is applied. The two second power terminals 15 are spaced apart from each other in the second direction y. The first power terminal 14 is positioned between the two second power terminals 15. As shown in FIG. 18, the two second power terminals 15 are positioned on the same side as the first power terminal 14 in the first direction x, with respect to the first mounting section 1121 and the second mounting section 1122. The second power terminals 15 are spaced apart from the first mounting section 1121 and the second mounting section 1122. Each second power terminal 15 extends in the first direction x, protruding from the sealing part 50 toward the first side (the x1 side) in the first direction x. As shown in FIGS. 17 and 21, each second power terminal 15 includes a portion covered with the sealing part 50 and a portion exposed from the sealing part 50. The portion of each second power terminal 15 that is covered with the sealing part 50 is bonded to the second conductive member 32. The portion of each second power terminal 15 that is exposed from the sealing part 50 is used as the N terminal of the semiconductor device B1 described above.

As shown in FIGS. 18 and 21, the two third power terminal 16 are bonded to the second mounting section 1122. The type of bonding is not particularly limited. The bonding may be made by using a conductive bonding material (e.g., solder) not shown in the figures, by laser welding, or by crimping. Each third power terminal 16 is electrically connected to the first electrodes 211 of the second elements 21B via the second mounting section 1122. Each third power terminal 16 is electrically connected to the second electrodes 212 of the first elements 21A via the second mounting section 1122 and the first conductive member 31. The two third power terminals 16 output AC power converted by the semiconductor element 21 (the first elements 21A and the second elements 21B). In short, each third power terminal 16 is an AC output terminal. The two third power terminals 16 are spaced apart from each other in the second direction y. As shown in FIG. 18, the two third power terminals 16 are positioned on the side opposite the first mounting section 1121 with the second mounting section 1122 between them in the first direction x. The third power terminals 16 extend from the second mounting section 1122 toward the second side (the x2 side) in the first direction x, protruding from the sealing part 50 toward the second side (x2 side) in the first direction x. As shown in FIGS. 17 and 21, each third power terminal 16 includes a portion covered with the sealing part 50 and a portion exposed from the sealing part 50. The portion of each third power terminal 16 that is covered with the sealing part 50 is bonded to the second mounting section 1122. The portion of each third power terminal 16 that is exposed from the sealing part 50 is used as the output terminal of the semiconductor device B1 described above.

The pair of control wirings 60 form a portion of a conduction path connecting the signal terminals 17 and the semiconductor elements 21. As shown in FIGS. 17, 18, and 24, the pair of control wirings 60 include a first wiring 601 and a second wiring 602. The first wiring 601 is positioned between the plurality of first elements 21A and the first and second power terminals 14 and 15 in the first direction x. As shown in FIGS. 18 and 24, the first wiring 601 is bonded to the first mounting section 1121. The second wiring 602 is positioned between the plurality of second elements 21B and the two third power terminals 16 in the first direction x. As shown in FIGS. 18 and 24, the second wiring 602 is bonded to the second mounting section 1122. The pair of control wirings 60 include an insulating layer 61, a plurality of wiring layers 62, a metal layer 63, and a plurality of sleeves 64. The pair of control wirings 60 are covered with the sealing part 50, except over a portion of each sleeve 64. Unless otherwise specifically noted, the description of insulating layer 61, the wiring layers 62, the metal layer 63, and the sleeves 64 given below commonly applies to both the control wirings 60 (the first wiring 601 and the second wiring 602).

As shown in FIG. 24, the insulating layer 61 includes regions disposed between the wiring layers 62 and the metal layer 63 in the thickness direction z. The insulating layer 61 is made of a ceramic material, for example. Alternatively, the insulating layer 61 may be formed from an insulating resin sheet rather than a ceramic material.

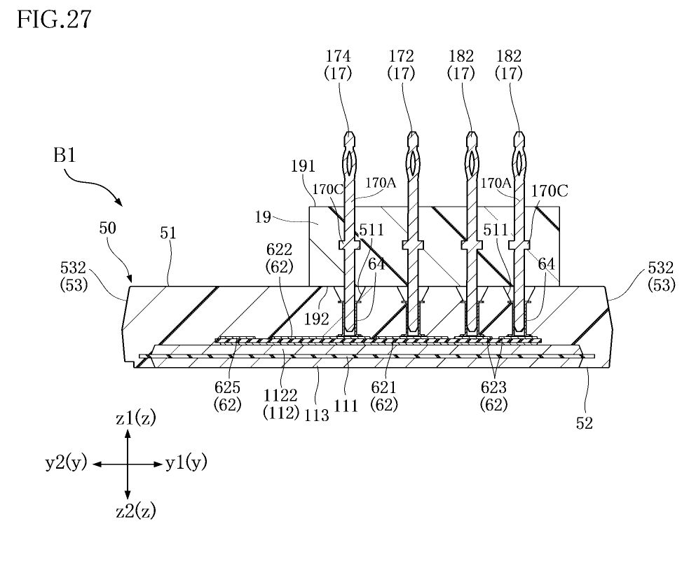

As shown in FIG. 24, the wiring layers 62 are positioned above (the z1 side) the insulating layer 61 in the thickness direction z. The composition of the wiring layers 62 includes copper. As shown in FIGS. 18 and 27, the wiring layers 62 include a first wiring layer 621, a second wiring layer 622, a third wiring layer 623, a fourth wiring layer 624, and a fifth wiring layer 625.

As shown in FIG. 24, the metal layer 63 is positioned on the side opposite the wiring layers 62 with the insulating layer 61 between them in the thickness direction z. The composition of the metal layer 63 includes copper. The metal layer 63 of the first wiring 601 is bonded to the first mounting section 1121 via an adhesive layer not shown in the figures. The metal layer 63 of the second wiring 602 is bonded to the second mounting section 1122 via an adhesive layer not shown in the figures. The material of these adhesive layers may be either conductive or non-conductive. For example, the adhesive layers may be solder.

As shown in FIGS. 24 and 27, each sleeve 64 is bonded to one of the wiring layers 62 via a conductive bonding layer (such as soler) not shown in the figures. The sleeves 64 are made of a conductive material, such as metal. Each sleeve 64 has a tubular shape extending in the thickness direction z. Each sleeve 64 is electrically bonded to the corresponding wiring layer 62 at one end (the end on the z2 side in the thickness direction z). As shown in FIG. 24, the other end of each sleeve 64 (the end on the z1 side in the thickness direction z) is exposed from the sealing part 50. Each sleeve 64 is an example of the connecting part of the present disclosure.

As shown in FIG. 18, one of the thermistors 22 spans and is electrically bonded to the pair of third wiring layers 623 of the first wiring 601. As shown in FIG. 18, the other thermistor 22 spans and is electrically bonded to the pair of third wiring layers 623 of the second wiring 602. Each thermistor 22 is an NTC (negative temperature coefficient) thermistor, for example. An NTC thermistor has a resistance that gradually decreases as the temperature increases. The thermistors 22 are used as temperature sensors for the semiconductor device B1.

As shown in FIGS. 15 and 24, each signal terminal 17 is made with a metal pin extending in the thickness direction z. Each signal terminal 17 protrudes from the top surface 51 of the sealing part 50, which will be described later. Each signal terminal 17 is press-fitted into the corresponding sleeve 64 of the control wirings 60. Thus, each signal terminal 17 is supported by the sleeve 64 and is electrically connected to a corresponding wiring layer 62. The plurality of signal terminals 17 include a first signal terminal 171, a second signal terminal 172, a third signal terminal 173, a fourth signal terminal 174, a pair of fifth signal terminals 181, a pair of sixth signal terminals 182, and a seventh signal terminal 183. These first signal terminal 171, second signal terminal 172, third signal terminal 173, fourth signal terminal 174, fifth signal terminal 181, sixth signal terminals 182, and seventh signal terminal 183 extend through the wiring board E1 and transmit signals to and from the wiring board E1.

The first signal terminal 171 is press-fitted into a sleeve 64 that is bonded to the first wiring layer 621 of the first wiring 601 among the plurality of sleeves 64. Thus, the first signal terminal 171 is supported by the sleeve 64 and is electrically connected to the first wiring layer 621 of the first wiring 601. Also, the first signal terminal 171 is electrically connected to the third electrode 213 of each first element 21A. The first signal terminal 171 receives the gate voltage for driving the first elements 21A.

The second signal terminal 172 is press-fitted into a sleeve 64 that is bonded to the first wiring layer 621 of the second wiring 602 among the plurality of sleeves 64. Thus, the second signal terminal 172 is supported by the sleeve 64 and is electrically connected to the first wiring layer 621 of the second wiring 602. Also, the second signal terminal 172 is electrically connected to the third electrodes 213 of the second elements 21B. The gate voltage for driving the second elements 21B is applied to the second signal terminal 172.

As shown in FIG. 18, the third signal terminal 173 is positioned next to the first signal terminal 171 in the second direction y. The third signal terminal 173 is press-fitted into a sleeve 64 that is bonded to the second wiring layer 622 of the first wiring 601 among the plurality of sleeves 64. Thus, the third signal terminal 173 is supported by the sleeve 64 and is electrically connected to the second wiring layer 622 of the first wiring 601. Also, the third signal terminal 173 is electrically connected to the fourth electrodes 214 of the first elements 21A. The third signal terminal 173 receives a voltage that corresponds to the maximum current flowing through the fourth electrodes 214 of the plurality of first elements 21A.

As shown in FIG. 18, the fourth signal terminal 174 is positioned next to the second signal terminal 172 in the second direction y. The fourth signal terminal 174 is press-fitted into a sleeve 64 that is bonded to the second wiring layer 622 of the second wiring 602 among the plurality of sleeves 64. Thus, the fourth signal terminal 174 is supported by the sleeve 64 and is electrically connected to the second wiring layer 622 of the second wiring 602. Aso, the fourth signal terminal 174 is electrically connected to the fourth electrodes 214 of the second elements 21B. The fourth signal terminal 174 receives a voltage that corresponds to the maximum current flowing through the fourth electrodes 214 of the plurality of second elements 21B.

As shown in FIG. 18, the pair of fifth signal terminals 181 is positioned on the side opposite the third signal terminal 173 with the first signal terminal 171 between them in the second direction y. The fifth signal terminals 181 are arranged next to each other in the second direction y. Each fifth signal terminal 181 is press-fitted into a sleeve 64 that is bonded to one of the third wiring layers 623 of the first wiring 601. Thus, each fifth signal terminal 181 is supported by the sleeve 64 and is electrically connected to the corresponding third wiring layer 623 of the first wiring 601. Also, each fifth signal terminal 181 is electrically connected to the thermistor 22 that is disposed on the first wiring 601.

As shown in FIG. 18, the pair of sixth signal terminals 182 is positioned on the side opposite the fourth signal terminal 174 with the second signal terminal 172 between them in the second direction y. The sixth signal terminals 182 are arranged next to each other in the second direction y. Each sixth signal terminal 182 is press-fitted into a sleeve 64 that are bonded to one of the two third wiring layers 623 of the second wiring 602. Thus, each sixth signal terminal 182 is supported by the sleeve 64 and is electrically connected to the corresponding third wiring layer 623 of the second wiring 602. Also, each sixth signal terminal 182 is electrically connected to the thermistor 22 that is disposed on the second wiring 602.

As shown in FIG. 18, the seventh signal terminal 183 is positioned on the side opposite the first signal terminal 171 with the third signal terminal 173 between them in the second direction y. The seventh signal terminal 183 is press-fitted into a sleeve 64 that is bonded to the fifth wiring layer 625 of the first wiring 601. Thus, the seventh signal terminal 183 is supported by the sleeve 64 and is electrically connected to the fifth wiring layer 625 of the first wiring 601. Also, the seventh signal terminal 183 is electrically connected to the first mounting section 1121. The seventh signal terminal 183 receives a voltage that corresponds to the DC power supplied to the first power terminal 14.

As shown in FIGS. 15, 19, 24, and 27 in particular, the holding part 19 covers a portion of each signal terminal 17 and supports the signal terminals 17. In the present embodiment, the semiconductor device B1 includes two holding parts 19. A first holding part 19 collectively covers a portion of each of the first signal terminal 171, the third signal terminal 173, the fifth signal terminals 181, and the seventh signal terminal 183. The other holding part 19 is positioned on the x2 side in the first direction x from the first holding part 19 and collectively covers a portion of each of the second signal terminal 172, the fourth signal terminal 174, and the sixth signal terminals 182. In the illustrated example, each holding part 19 has the shape of a rectangular parallelepiped that is elongated in the second direction y. Each holding part 19 covers the relevant signal terminals 17 aligned in the second direction y. The holding parts 19 are electrically insulative and contain, for example, an epoxy resin. The holding parts 19 may be formed by molding. The shape of the holding parts 19 is not limited to a rectangular parallelepiped as shown in the figures, and various modifications may be made.

Each holding part 19 includes a holding-part top surface 191 and a holding-part bottom surface 192. The holding-part top surface 191 is positioned on the z1 side in the thickness direction z, facing the z1 side in the thickness direction z. The holding-part bottom surface 192 is positioned on the z2 side in the thickness direction z, facing the z2 side in the thickness direction z.

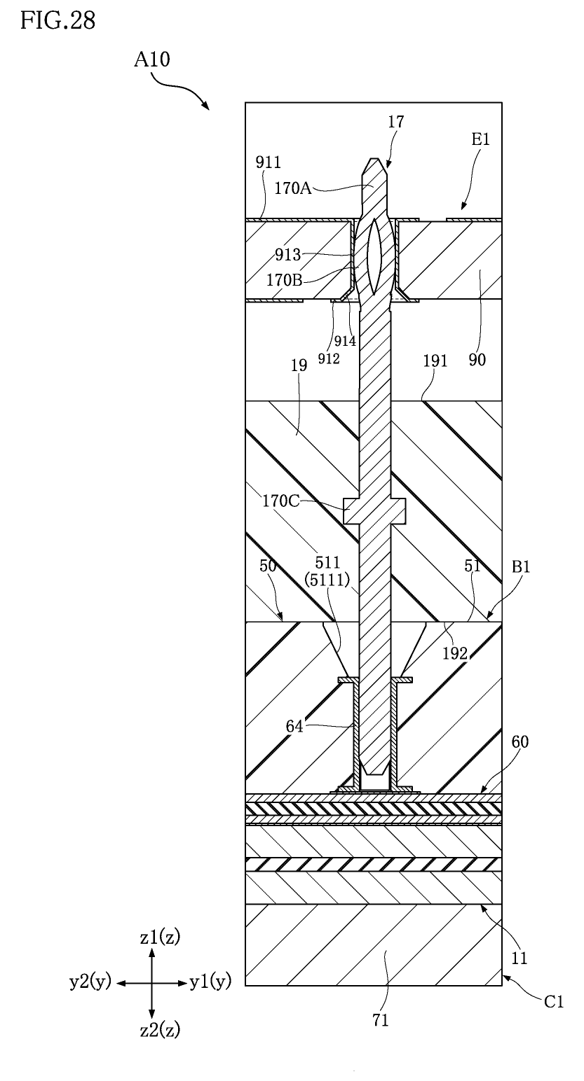

In the present embodiment, each signal terminal 17 includes a protruding portion 170C as shown in FIGS. 24, 27, and 28. The protruding portion 170C is provided in the middle region of the base portion 170A along the thickness direction z. The protruding portion 170C protrudes beyond the base portion 170A in a direction intersecting the thickness direction z. In the illustrated example, the protruding portion 170C protrudes beyond the base portion 170A in a direction perpendicular to the thickness direction z. Each holding part 19 covers the protruding portion 170C and a portion of the base portion 170A of each relevant signal terminal 17.

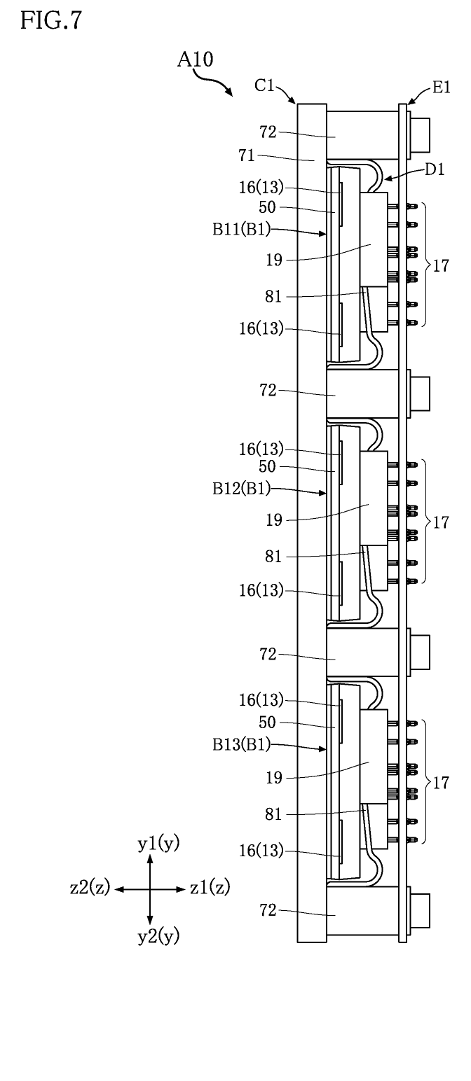

As shown in FIGS. 7 to 11, and 28, each holding part 19 is positioned between the sealing part 50 and the wiring board E1 in the thickness direction z. As shown in FIGS. 24, 27, and 28, each holding part 19 (the holding-part bottom surface 192) is in contact with the sealing part 50 (the top surface 51 described later).

The first wires 41, the second wires 42, the third wires 43, and the fourth wire 44 electrically connect components that are spaced apart from each other. The first wires 41, the second wires 42, the third wires 43, and the fourth wire 44 are bonding wires. FIGS. 17, and 21 to 24 omit the illustration of the first wires 41, the second wires 42, the third wires 43, and the fourth wire 44.

As shown in FIG. 18, the first wires 41 include those electrically connected to the third electrodes 213 of the respective first elements 21A and to the fourth wiring layer 624 of the first wiring 601. As shown in FIG. 18, the third wires 43 include those electrically bonded to the fourth wiring layer 624 of the first wiring 601 and to the first wiring layer 621 of the first wiring 601. Thus, the first signal terminal 171 is electrically connected to the third electrode 213 of each first element 21A. The composition of the first wires 41 and the third wires 43 includes gold (Au). Alternatively, the composition of the first wires 41 and the third wires 43 may include copper or aluminum.

As shown in FIG. 18, in addition, the first wires 41 include those electrically bonded to the third electrodes 213 of the respective second elements 21B and to the fourth wiring layer 624 of the second wiring 602. As shown in FIG. 18, in addition, the third wires 43 include those electrically bonded to the fourth wiring layer 624 of the second wiring 602 and to the first wiring layer 621 of the second wiring 602. Thus, the second signal terminal 172 is electrically connected to the third electrode 213 of each second element 21B.

As shown in FIG. 18, the second wires 42 include those electrically bonded one of the two fourth electrodes 214 of the respective first elements 21A and also to the second wiring layer 622 of the first wiring 601. Thus, the third signal terminal 173 is electrically connected to one of the two fourth electrodes 214 of each first element 21A. As shown in FIG. 18, the second wires 42 include those electrically bonded one of the two fourth electrodes 214 of the respective second elements 21B and also to the second wiring layer 622 of the second wiring 602. Thus, the fourth signal terminal 174 is electrically connected to one of the two fourth electrodes 214 of each second element 21B. The composition of the second wires 42 includes gold. Alternatively, the composition of the second wires 42 may include copper or aluminum. In some example, each semiconductor element 21 (each of the first elements 21A and the second elements 21B) may include no fourth electrode 214. In that case, the second wires 42 are bonded to the second electrodes 212 of the respective semiconductor elements 21.

As shown in FIG. 18, the fourth wire 44 is electrically bonded to the fifth wiring layer 625 of the first wiring 601 and also to the first mounting section 1121. Thus, the seventh signal terminal 183 is electrically connected to the first electrode 211 of each first element 21A via the first mounting section 1121. The composition of the fourth wire 44 includes gold. Alternatively, the composition of the fourth wire 44 may include copper or aluminum.

As shown in FIGS. 18 and 21, the first conductive member 31 is electrically bonded to the second electrodes 212 of the respective first element 21A and to the second mounting section 1122. Thus, the second electrode 212 of each first element 21A is electrically connected to the second mounting section 1122. The composition of the first conductive member 31 includes copper. The first conductive member 31 is a metal clip. As shown in FIGS. 18 and 21, the first conductive member 31 includes a main body 311, a plurality of first bonding portions 312, and a plurality of second bonding portions 313.

The main body 311 forms the major part of the first conductive member 31. As shown in FIG. 18, the main body 311 extends in the first direction x. As shown in FIGS. 18 and 21, the main body 311 spans the gap between the first mounting section 1121 and the second mounting section 1122. In the example shown in FIG. 18, the main body 311 is formed with a plurality of through-holes. Each through-hole penetrates the main body 311 in the thickness direction z. The through-holes overlap with the gap between the first mounting section 1121 and the second mounting section 1122 in plan view. In the process of forming the sealing part 50, this facilitates the flow of resin for forming the sealing part 50 into the region below (the z2 side in the thickness direction z) the main body 311 in the thickness direction z.

As shown in FIGS. 18, 21, and 22, each first bonding portion 312 is bonded to the second electrode 212 of a corresponding first element 21A. Each first bonding portion 312 faces the second electrode 212 of the first element 21A. In plan view, each first bonding portion 312 extends from the main body 311 toward the x1 side in the first direction x. In the illustrated example, each first bonding portion 312 has bifurcated ends extending from the main body 311, but bifurcation is not required. The base end of each first bonding portion 312 (the end connected to the main body 311) is bent downward in the thickness direction z (the z2 side in the thickness direction z). Thus, the distal end (the end remote from the main body 311) of each first bonding portion 312 is positioned below the main body 311 in the thickness direction z (the z2 side in the thickness direction z).

As shown in FIGS. 18 and 21, the second bonding portions 313 are bonded to the second mounting section 1122. Each second bonding portion 313 faces the second mounting section 1122. In plan view, each second bonding portion 313 extends from the main body 311 toward the x2 side in the first direction x. The base end of each second bonding portion 313 (the end connected to the main body 311) is bent downward in the thickness direction z (the z2 side in the thickness direction z). Thus, the distal end (the end remote from the main body 311) of each second bonding portion 313 is positioned below the main body 311 in the thickness direction z (the z2 side in the thickness direction z).

As shown in FIG. 22, the semiconductor device B1 additionally includes a first conductive bonding layer 33. The first conductive bonding layer 33 is disposed between the second electrode 212 of a first elements 21A and a first bonding portion 312. The first conductive bonding layer 33 electrically bonds the second electrode 212 of the first element 21A and the first bonding portion 312. In one example, the first conductive bonding layer 33 is solder. In another example, the first conductive bonding layer 33 may contain sintered metal particles.

As shown in FIG. 21, the semiconductor device B1 additionally includes a second conductive bonding layer 34. The second conductive bonding layer 34 is disposed between the second mounting section 1122 and a second bonding portion 313. The second conductive bonding layer 34 electrically bonds the second mounting section 1122 and the second bonding portion 313. In one example, the second conductive bonding layer 34 is solder. In another example, the second conductive bonding layer 34 may contain sintered metal particles.

As shown in FIG. 17, the second conductive member 32 is electrically bonded to the second electrodes 212 of the respective second element 21B and to the two second power terminals 15. This electrically connect the second electrode 212 of each second element 21B to the two second power terminals 15. The composition of the second conductive member 32 includes copper. The second conductive member 32 is a metal clip. As shown in FIGS. 17, and 21 to 26, the second conductive member 32 includes a main body 321, a plurality of third bonding portions 322, and a pair of fourth bonding portions 323.

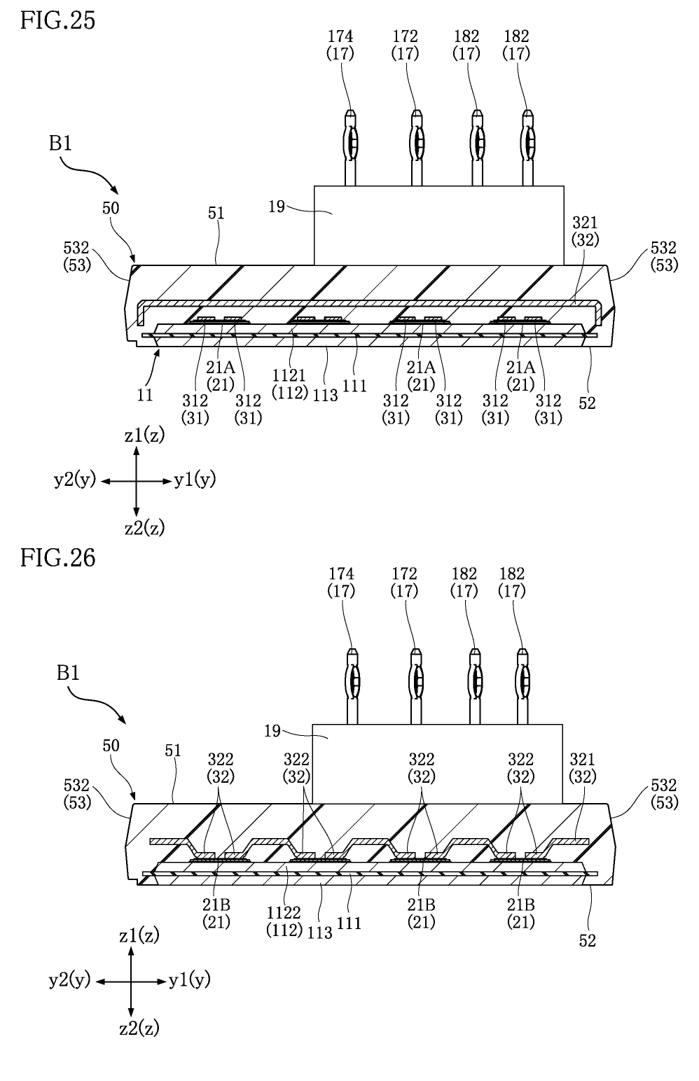

The main body 321 forms the major part of the second conductive member 32. As shown in FIGS. 21 and 25, the main body 321 is disposed parallel to the upper surface of the first mounting section 1121 and also to the upper surface of the second mounting section 1122. The main body 321 is spaced apart from the main body 311 of the first conductive member 31 and also from the first mounting section 1121 and the second mounting section 1122.

As shown in FIGS. 17, 21, and 23, each third bonding portion 322 is bonded to the second electrode 212 of a corresponding second element 21B. Each third bonding portion 322 faces the second electrode 212 of the second element 21B. In plan view, each third bonding portion 322 extends from the main body 321 in the second direction y. The base end of each third bonding portion 322 (the end connected to the main body 321) is bent downward in the thickness direction z (the z2 side in the thickness direction z). Thus, the distal end (the end remote from the main body 321) of each third bonding portion 322 is positioned below the main body 321 in the thickness direction z (the z2 side in the thickness direction z).

As shown in FIGS. 17 and 21, each fourth bonding portion 323 is bonded to one of the two second power terminals 15. Each fourth bonding portion 323 faces the corresponding second power terminal 15.

As shown in FIG. 23, the semiconductor device B1 additionally includes a third conductive bonding layer 35. The third conductive bonding layer 35 is disposed between the second electrode 212 of a second element 21B and a third bonding portion 322. The third conductive bonding layer 35 electrically bonds the second electrode 212 of the second element 21B and the third bonding portion 322. In one example, the third conductive bonding layer 35 is solder. In another example, the third conductive bonding layer 35 may contain sintered metal particles.

As shown in FIG. 21, the semiconductor device B1 additionally includes a fourth conductive bonding layer 36. The fourth conductive bonding layer 36 is disposed between a second power terminal 15 and a fourth bonding portion 323. The fourth conductive bonding layer 36 electrically bonds the second power terminal 15 and the fourth bonding portion 323. In one example, the fourth conductive bonding layer 36 is solder. In another example, the fourth conductive bonding layer 36 may contain sintered metal particles.

As shown in FIGS. 15 to 27, the sealing part 50 covers the semiconductor elements 21, the first conductive member 31, the second conductive member 32, the first wires 41, the second wires 42, the third wires 43, and the fourth wire 44. The sealing part 50 also covers a portion of each of the supporting substrate 11, the power terminals 13, and the signal terminals 17. The sealing part 50 is electrically insulative. For example, the sealing part 50 contains a black epoxy resin. The sealing part 50 may be formed by molding. As shown in FIGS. 15 to 17, and 19 to 27, the sealing part 50 includes a top surface 51, a plurality of second recesses 511, a bottom surface 52, a plurality of resin side surfaces 53, and a pair of recesses 55.

As shown in FIGS. 21, and 24 to 27, the top surface 51 faces the same side (the z1 side in the thickness direction z) as the upper surface of the first mounting section 1121 and the upper surface of the second mounting section 1122 in the thickness direction z. The top surface 51 of sealing part 50 is in contact with the attachment member D1.

Each second recess 511 is recessed from the top surface 51 toward the z2 side in the thickness direction z. The second recesses 511 are provided for the respective sleeves 64. Each second recess 511 overlaps with the corresponding sleeve 64 as viewed in the thickness direction z. Each second recess 511 includes a portion that is inclined radially inward of the sleeve 64 toward the z2 side in the thickness direction z (a second portion 5111). In the present embodiment, the entire or substantially entire second recess 511 is inclined radially inward of the sleeve 64 toward the z2 side in the thickness direction z, forming a shape resembling a cone.

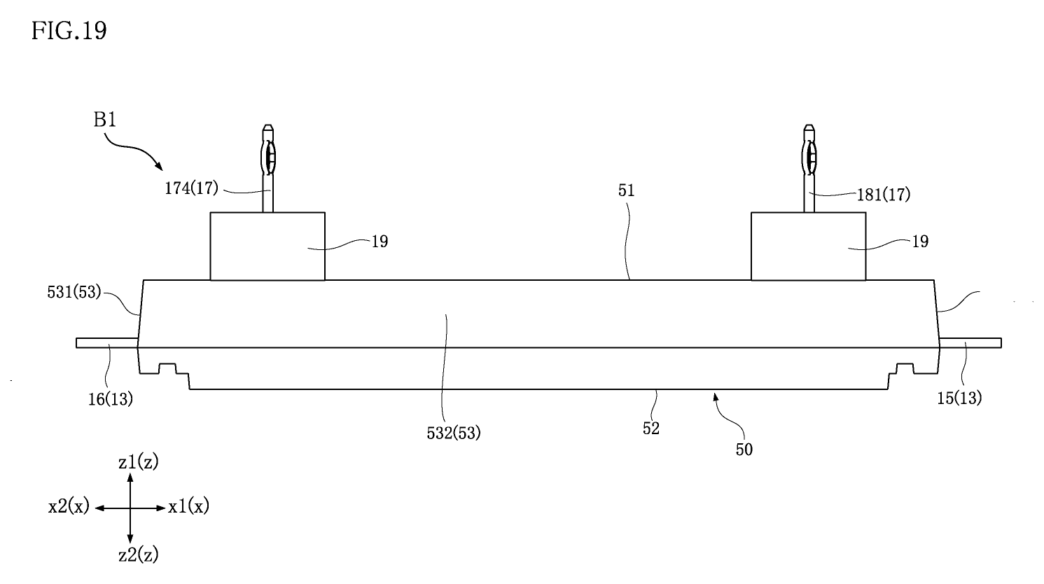

As shown in FIGS. 19, 21, and 24 to 27, the bottom surface 52 faces away from the top surface 51 in the thickness direction z (faces the z2 side in the thickness direction z). As shown in FIGS. 20, 21, and 24 to 27, the second wiring layer 113 of the supporting substrate 11 is exposed at the bottom surface 52. The bottom surface 52 of the semiconductor device B1 is in contact with the main body 71 of the heat sink C1.

Each resin side surface 53 is connected to the top surface 51. The plurality of resin side surfaces 53 include a pair of first side surfaces 531 and a pair of second side surfaces 532.

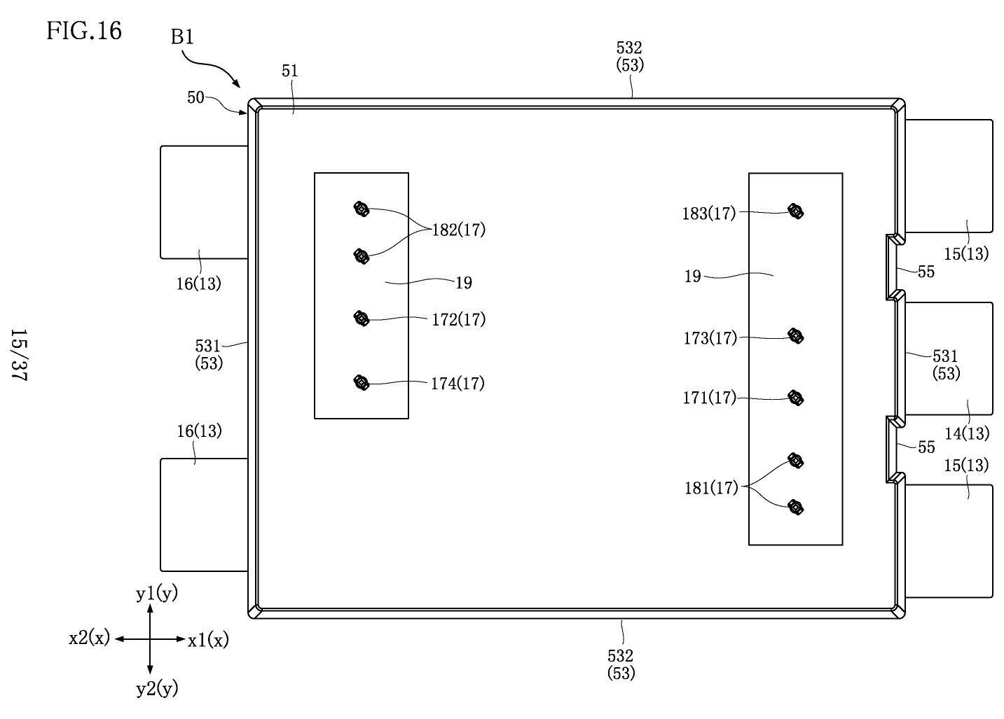

As shown in FIGS. 16, 17, 19 to 21, and 24, the two first side surfaces 531 are spaced apart from each other in the first direction x. The two first side surfaces 531 face away from each other in the first direction x and extend in the second direction y. The first side surfaces 531 are connected to the top surface 51. The first power terminal 14 and the two second power terminals 15 protrude from the first side surface 531 on the x1 side in the first direction x. The two third power terminals 16 protrude from the first side surface 531 on the x2 side in the first direction x.

As shown in FIGS. 16, 17, 20, and 25 to 27, the two second side surfaces 532 are spaced apart from each other in the second direction y. The two second side surfaces 532 face away from each other in the second direction y and extend in the first direction x. The second side surfaces 532 are connected to the top surface 51 and the bottom surface 52.

As shown in FIGS. 16, 17, and 20, each recess 55 is recessed in the first direction x from the first side surface 531 that is on the x1 side in the first direction x. In the thickness direction z, each recess 55 extends from the top surface 51 to the bottom surface 52. The two recesses 55 are positioned on either side of the first power terminal 14 in the second direction y.

The structure of the semiconductor device B1 described above is merely an example and should not be construed as limiting the present disclosure. Various changes may be made to, for example, the number of signal terminals 17, the signals transmitted to and from the signal terminals 17, the number of semiconductor elements 21, the structures of the first wiring 601 and the second wiring 602. The supporting substrate 11 may include a conductive plate bonded to the first wiring layer 112 (each of the first mounting section 1121 and the second mounting section 1122). In this case, the semiconductor elements 21 (the first elements 21A and the second elements 21B) and the pair of control wirings 60 are mounted on the conductive plate.

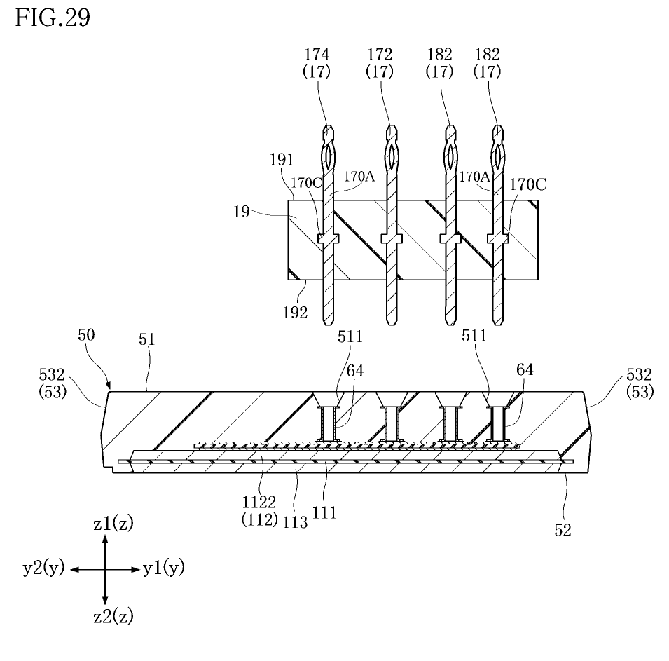

The following describes an example of a method for manufacturing a semiconductor device B1, with reference to FIGS. 29 to 31. FIGS. 29 to 31 are sectional views each showing a step of the method for manufacturing a semiconductor device B1. FIGS. 29 to 31 show a section that corresponds to the section shown in FIG. 27.

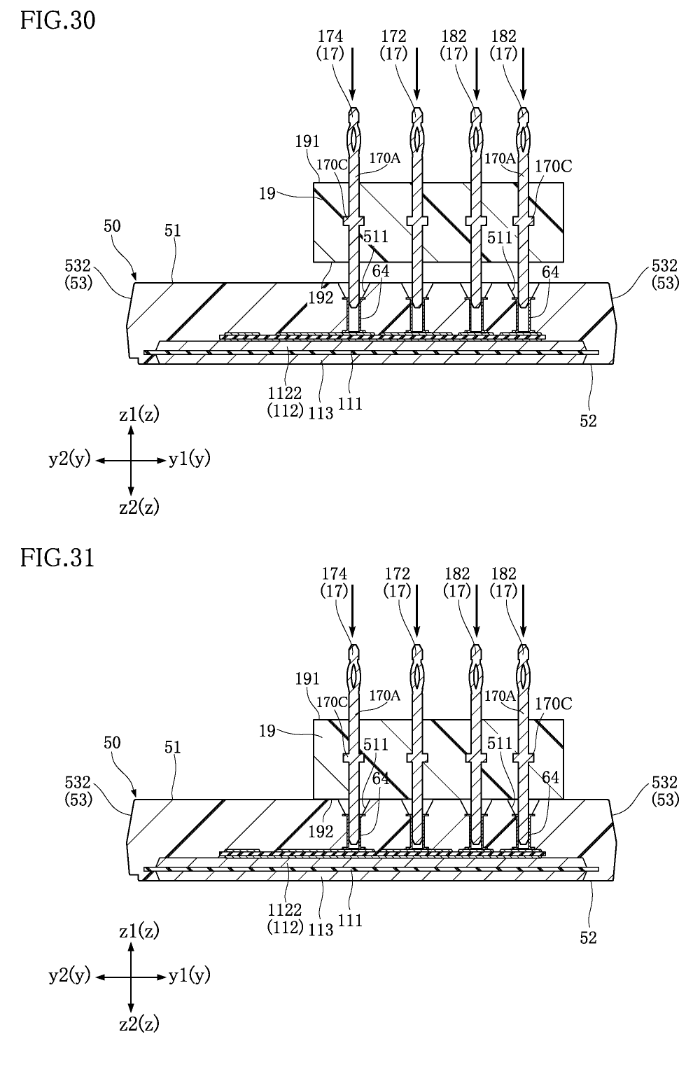

FIG. 29 shows the state before the signal terminals 17 are press-fitted into the sleeves 64. As shown in the figure, the signal terminals 17 are collectively held by the holding part 19. Subsequently, as shown in FIG. 30, the signal terminals 17 are inserted into the corresponding sleeves 64. The step of inserting the signal terminals 17 into the sleeves 64 is performed while the holding part 19 covers and holds a portion of each signal terminal 17. The signal terminals 17 held by the holding part 19 are press-fitted into the corresponding sleeves 64. This may be done by pressing the signal terminals 17 toward the z2 side in the thickness direction z, or by pressing the holding part 19 toward the z2 side in the thickness direction z.

As the signal terminals 17 are pressed further into the corresponding sleeves 64, the holding part 19 (the holding-part bottom surface 192) abuts the sealing part 50 (the top surface 51) as shown in FIG. 31. In this state, the end of each signal terminal 17 on the z2 side in the thickness direction z is pressed into the sleeve 64 by a predetermined length.

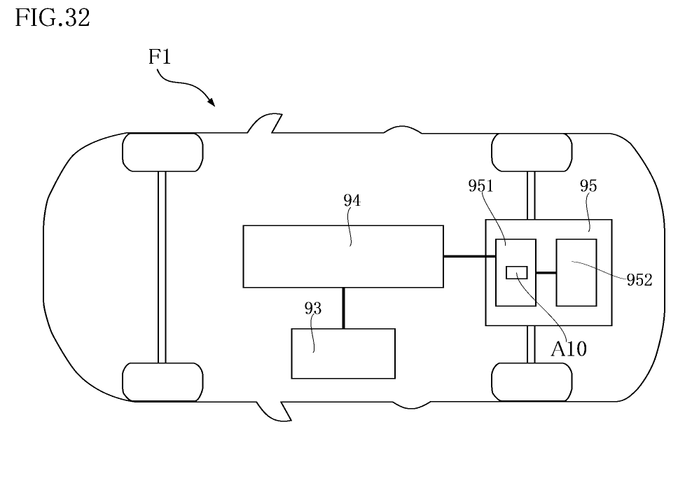

FIG. 32 is a schematic view of a vehicle F1 that incorporates a power conversion unit A10. For example, the vehicle F1 is an electric vehicle (EV).

As shown in FIG. 32, the vehicle F1 includes an on-board charger 93, a storage battery 94, and a drive system 95. The on-board charger 93 wirelessly receives power from an outdoor power supply facility (not shown). Alternatively, the on-board charger 93 may receive power from a power supply facility via a wired connection. The on-board charger 93 includes a step-up DC-DC converter. The voltage of the power supplied to the on-board charger 93 is increased by the converter and supplied to the storage battery 94. For example, the voltage is increased to 600 V.

The drive system 95 propels the vehicle F1. The drive system 95 includes an inverter 951 and a drive source 952. The power conversion unit A10 (the semiconductor devices B1) forms part of the inverter 951. The power stored in the storage battery 94 is supplied to the inverter 951. The storage battery 94 supplies DC power to the inverter 951. In contrast to the power system shown in FIG. 32, an additional step-up DC-DC converter may be provided between the storage battery 94 and the inverter 951. The inverter 951 converts DC power to AC power. The inverter 951, including the power conversion unit A10 (the semiconductor devices B1), is electrically connected to the drive source 952. The drive source 952 includes an AC motor and a transmission. When AC power converted by the inverter 951 is supplied to the drive source 952, the AC motor rotates and delivers the torque to the transmission. The transmission reduces the rotational speed transmitted from the AC motor as needed and rotates the drive shaft of the vehicle F1. As a result, the vehicle F1 is driven. While the vehicle F1 is driving, the rotational speed of the AC motor needs to be adjusted based on the position of the accelerator pedal and other relevant information. The power conversion unit A10 (the semiconductor devices B1) in the inverter 951 is necessary for outputting AC power with a frequency appropriately adjusted to match the target rotational speed of the AC motor.

The operation and effects of the power conversion unit A10 are as follows.

The power conversion unit A10 includes a holding part 19 that covers a portion of each of a plurality of signal terminals 17 inserted into corresponding sleeves 64. That is, the signal terminals 17 are inserted into the corresponding sleeves 64 and collectively held by the holding part 19. Holding the signal terminals 17 with the holding part 19 reduces their positional variations, thereby enabling smooth insertion of the signal terminals 17 into the through-holes 903 in the wiring board E1. This facilitates the assembly of the power conversion unit A10 (the semiconductor devices B1 and the wiring board E1).

In the present embodiment, the holding part 19 (the holding-part bottom surface 192) is in contact with the sealing part 50 (the top surface 51). When a plurality of signal terminals 17 are inserted into the corresponding sleeves 64, this configuration ensures that the signal terminals 17 are inserted into the sleeves 64 to a uniform length.

Each signal terminal 17 includes a base portion 170A extending in the thickness direction z and a protruding portion 170C. The protruding portion 170C protrudes beyond the base portion 170A in a direction intersecting the thickness direction z. This configuration prevents displacement of the signal terminals 17 held by the holding part 19 (displacement in the thickness direction z) when the signal terminals 17 are press-fitted into the corresponding sleeves 64.

The sealing part 50 includes a plurality of second recesses 511 recessed from the top surface 51 toward the z2 side in the thickness direction z. Each second recess 511 overlaps with the corresponding sleeve 64 as viewed in the thickness direction z. Each second recess 511 includes a second portion 5111 that is inclined radially inward of the sleeve 64 toward the z2 side in the thickness direction z. This configuration ensures that each signal terminal 17 is appropriately guided into the corresponding sleeve 64 by a second recess 511 when the signal terminals 17 are press-fitted into the sleeves 64. This facilitates the assembly of each semiconductor device B1.

In the power conversion unit A10, the wiring board E1 includes a base 90 formed with a first recess 904. The first recess 904 is recessed from the inner surface of a corresponding through-hole 903 and the second surface 902. The first recess 904 includes a first portion 9041 that is inclined radially inward of the through-hole 903 toward the z1 side in the thickness direction z. This configuration facilitates the press-fitting of the signal terminals 17 into the corresponding through-holes 903. Even if there may be some misalignment between the signal terminals 17 and the through-holes 903, the signal terminals 17 are appropriately guided into the through-holes 903 by the first recesses 904. This serves to facilitate the assembly of the power conversion unit A10 (the semiconductor devices B1 and the wiring board E1).

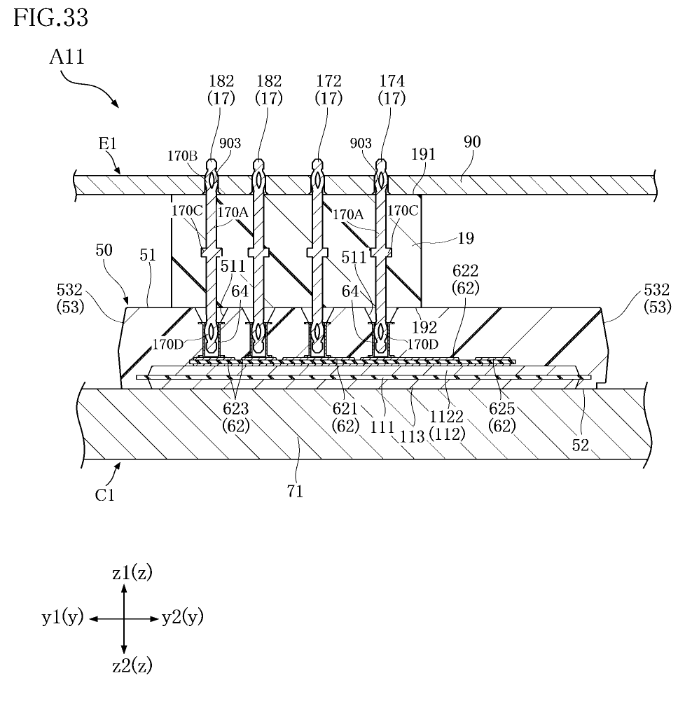

FIGS. 33 to 41 show variations and other embodiments of the power conversion unit according to the present disclosure. In these figures, elements that are identical or similar to those of the above embodiment are indicated by the same reference numerals, and redundant descriptions are omitted. The configurations of elements and components in the variations and embodiments and may be combined in any manner, provided that no technical inconsistencies arise.

### First Variation

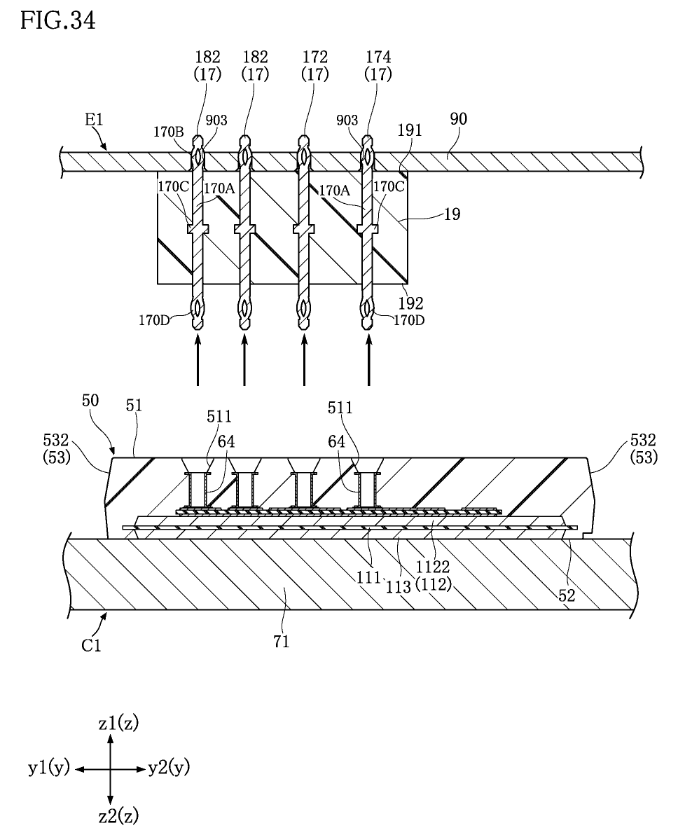

FIG. 33 shows a first variation of the power conversion unit A10. FIG. 33 is an enlarged partial sectional view of a power conversion unit A11 according to the first variation, and the section shown in the figure corresponds to that shown in FIG. 11. FIGS. 34 to 36 are sectional views illustrating one example of an assembly procedure of the power conversion unit A11.

The power conversion unit A11 of this variation differs from the power conversion unit A10 in configuration of the signal terminals 17. Unlike the power conversion unit A10, the power conversion unit A11 does not include the pedestals 72.

In the variation, each signal terminal 17 includes a second bulging portion 170D as shown in FIG. 33. The second bulging portion 170D is positioned on the z2 side in the thickness direction z with respect to the base portion 170A. The second bulging portion 170D is enlarged relative to the base portion 170A in a direction perpendicular to the thickness direction z. The second bulging portion 170D of each signal terminal 17 is press-fitted into a corresponding sleeve 64. In the variation, the power conversion unit A11 is configured such that each holding part 19 (the holding-part top surface 191) is in contact with the wiring board E1.

With reference to FIGS. 34 to 36, the following describes one example of an assembly procedure of the power conversion unit A11. FIGS. 34 to 36 are sectional views each illustrating a step of the assembly procedure of the power conversion unit A11. FIGS. 34 to 36 each show a section corresponding to that shown in FIG. 33.

First, as shown in FIG. 34, a plurality of signal terminals 17 are inserted into corresponding through-holes 903 in the wiring board E1. The first bulging portion 170B of each signal terminal 170 is press-fitted into the corresponding through-hole 903. This may be done by pressing the signal terminals 17 toward the wiring board E1 (the z1 side in the thickness direction z in FIG. 34), or by pressing the holding part 19 toward the wiring board E1. As the signal terminals 17 are pressed into the through-holes 903, the holding part 19 (the holding-part top surface 191) abuts the wiring board E1. Thus, the holding part 19 and the signal terminals 17 are supported by the wiring board E1.

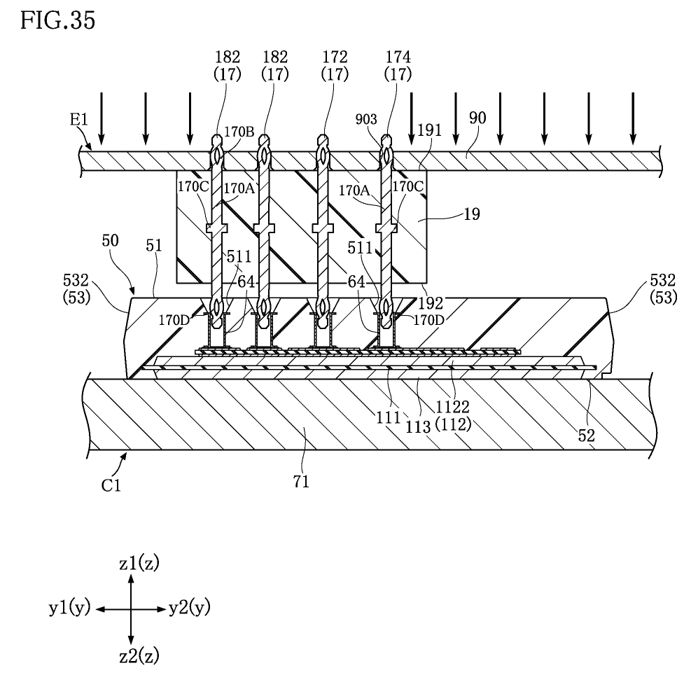

Subsequently, as shown in FIG. 35, the signal terminals 17 are inserted into corresponding sleeves 64. The signal terminals 17 are inserted into the sleeves 64 by, for example, pressing the wiring board E11 toward the sleeves 64 (the z2 side in the thickness direction z). This causes the second bulging portion 170D of each signal terminal 17 held by the wiring board E1 to be press-fitted into the corresponding sleeve 64.

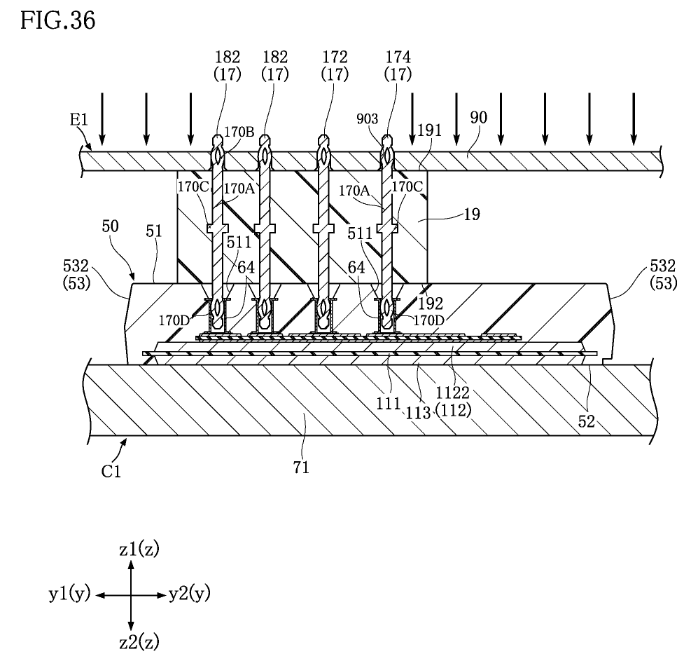

As the signal terminals 17 are pressed further into the sleeves 64, the holding part 19 (the holding-part bottom surface 192) abuts the sealing part 50 (the top surface 51) as shown in FIG. 36. In this state, the end of each signal terminal 17 on the z2 side in the thickness direction z is pressed into the sleeve 64 by a predetermined length.

The operation and effects of the power conversion unit A11 are as follows.

The power conversion unit A11 includes a holding part 19 that covers a portion of each of a plurality of signal terminals 17 inserted into corresponding sleeves 64. That is, the signal terminals 17 are inserted into the corresponding sleeves 64 and collectively held by the holding part 19. Holding the signal terminals 17 with the holding part 19 reduces their positional variations, thereby enabling smooth insertion of the signal terminals 17 into the through-holes 903 in the wiring board E1. This facilitates the assembly of the power conversion unit A11 (the semiconductor devices B1 and the wiring board E1).

The holding part 19 (the holding-part bottom surface 192) is in contact with the sealing part 50 (the top surface 51). When a plurality of signal terminals 17 are inserted into the corresponding sleeves 64, this configuration ensures that the signal terminals 17 are inserted into the sleeves 64 to a uniform length.

The holding part 19 (the holding-part top surface 191) is in contact with the wiring board E1. When a plurality of signal terminals 17 are inserted into the corresponding through-holes 903, this configuration ensures that the signal terminals 17 are inserted into the through-holes 903 to a uniform length. Additionally, the power conversion unit A11 achieves the same effects as the power conversion unit A10 of the above embodiment.

### Second Embodiment

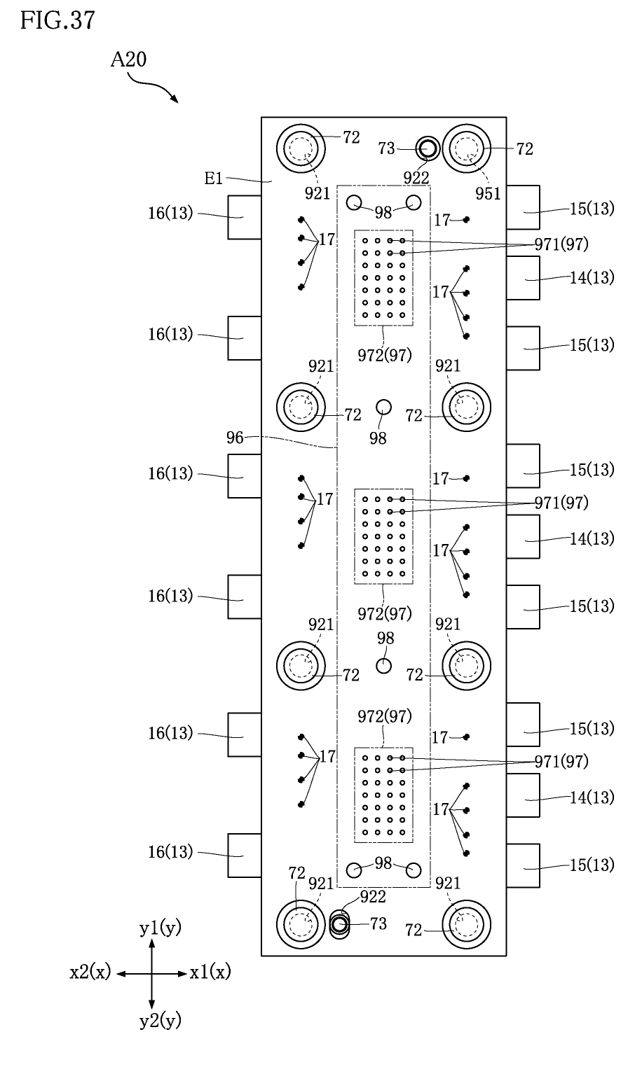

FIGS. 37 to 41 show a power conversion unit according to a second embodiment of the present disclosure. The power conversion unit A20 of the present embodiment additionally includes a wiring board 96, a plurality of interconnect wiring 97, and a plurality of positioning pins 98, as compared to the power conversion unit A10.

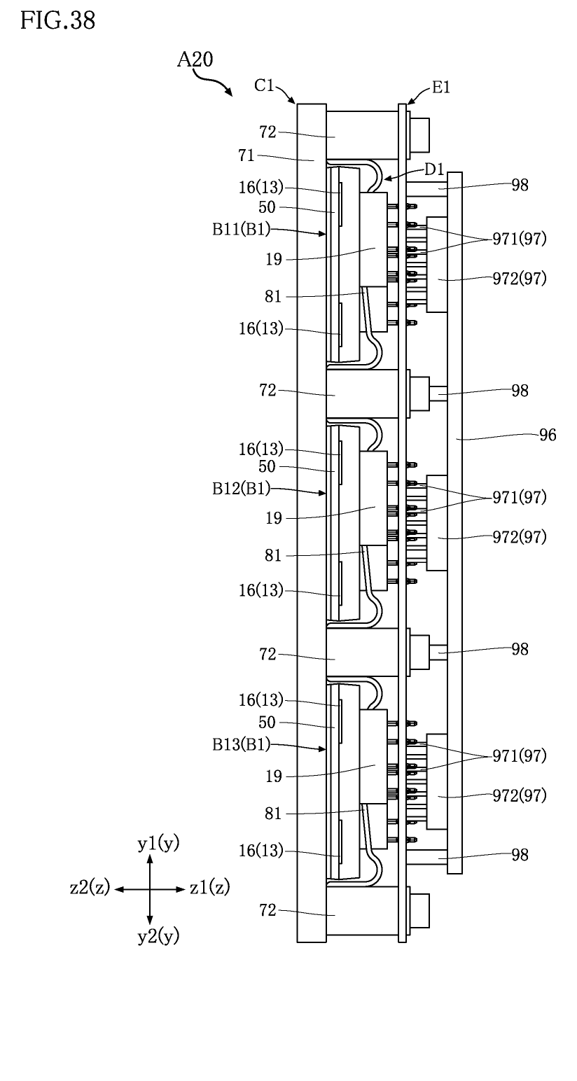

As shown in FIG. 38, the wiring board 96 is electrically connected to the wiring board E1 via the interconnect wirings 97. As shown in FIG. 37, the wiring board 96 extends in the second direction y. The wiring board 96 includes, among circuits for driving and controlling the semiconductor devices B1, circuits not being provided on the wiring board E1, such as a controller for controlling a gate driver. The wiring board 96 also includes an overheat protection circuit that is electrically connected to the pair of thermistors 22 included in each semiconductor devices B1. The wiring board 96 is positioned on the side opposite the heat sink C1 (the main body 71) with the wiring board E11 between them in the thickness direction z. The wiring board 96 overlaps with the wiring board E1 as viewed in the thickness direction z.

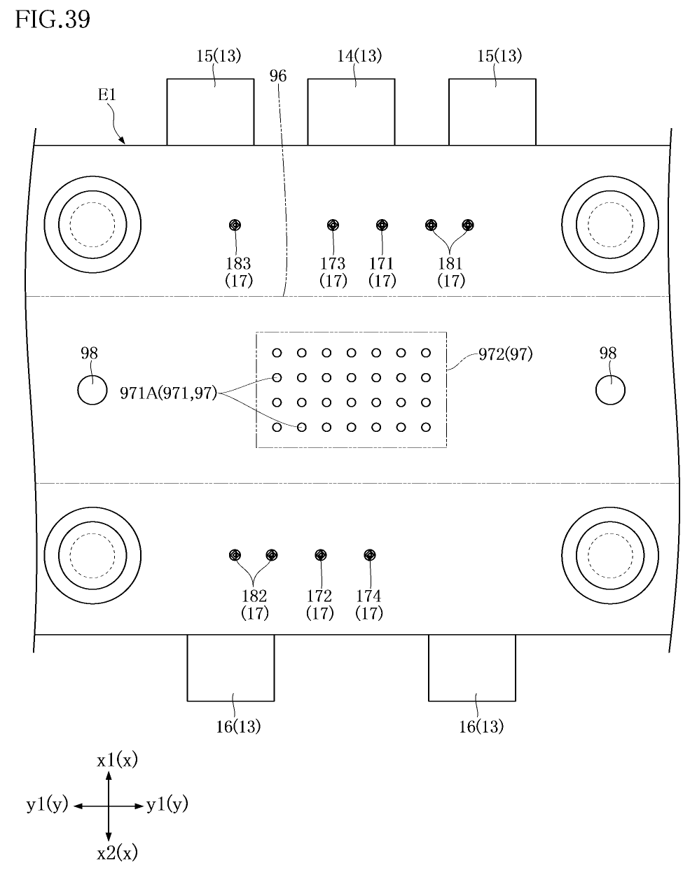

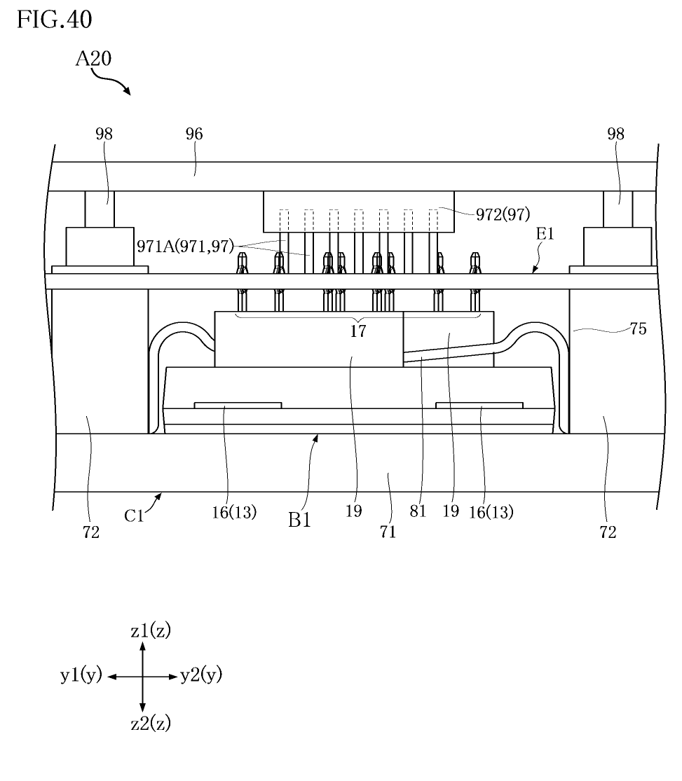

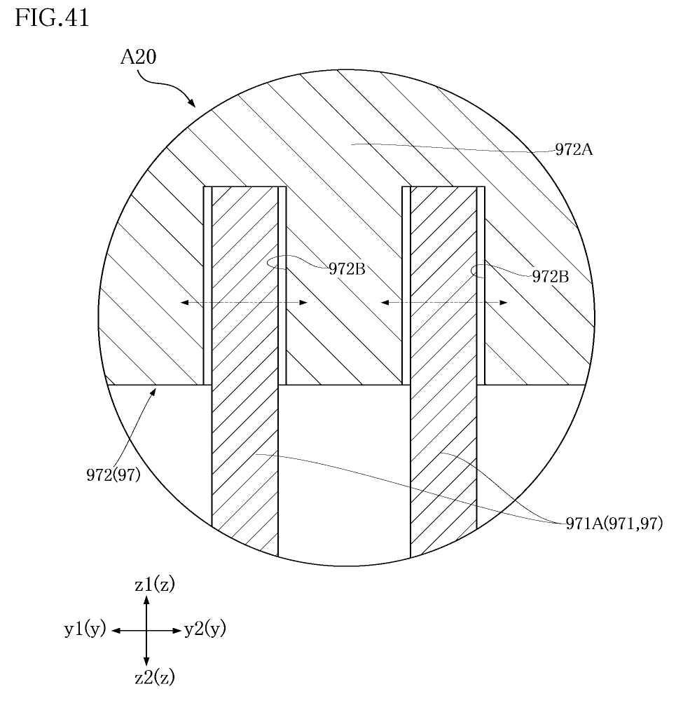

As shown in FIG. 38, the interconnect wirings 97 electrically connect the wiring board E1 and the wiring board 96. In the power conversion unit A20, each interconnect wiring 97 includes a first connecting portion 971 and a second connecting portion 972. As shown in FIG. 39, the first connecting portion 971 is electrically bonded to the wiring board E1. As shown in FIGS. 39 and 40, the first connecting portion 971 includes a plurality of connection pins 971A. The connection pins 971A extend in the thickness direction z. As shown in FIG. 40, the second connecting portion 972 is electrically bonded to the wiring board 96 and faces the first connecting portion 971. As shown in FIG. 41, the second connecting portion 972 includes a housing 972A and a plurality of connection holes 972B. The connection pins 971A are inserted into the corresponding connection holes 972B. Thus, the first connecting portion 971 is electrically connected to the second connecting portion 972.

As shown in FIG. 41, the housing 972A of the second connecting portion 972 is movable relative to the connection pins 971A in a direction perpendicular to the thickness direction z. Thus, the second connecting portion 972 is movable relative to the first connecting portion 971 in the direction perpendicular to the thickness direction z. This allows each interconnect wiring 97 to move in the direction perpendicular to the thickness direction z. The interconnect wirings 97 can be configured in this manner by applying the configuration of known connectors disclosed in JP-A-2018-113163, JP-A-2018-63886, JP-A- 2017-139101, and more.

As shown in FIG. 38, the positioning pins 98 are positioned between the wiring board E1 and the wiring board 96 in the thickness direction z. The positioning pins 98 are arranged at spaced intervals in the second direction y. Each positioning pin 98 is positioned between two semiconductor devices B1 that are located next to each other. The positioning pins 98 are used to position the wiring board 96 relative to the wiring board E1 and to support the wiring board 96.

The operation and effects of the power conversion unit A20 are as follows.

The power conversion unit A20 includes a holding part 19 that covers a portion of each of a plurality of signal terminals 17 inserted into the corresponding sleeves 64. That is, the signal terminals 17 are inserted into the corresponding sleeves 64 and collectively held by the holding part 19. Holding the signal terminals 17 with the holding part 19 reduces their positional variations, thereby enabling smooth insertion of the signal terminals 17 into the through-holes 903 in the wiring board E1. This facilitates the assembly of the power conversion unit A20 (the semiconductor devices B1 and the wiring board E1). Additionally, the power conversion unit A20 achieves the same effects as the power conversion unit A10 of the above embodiment.

The power conversion unit and the semiconductor device according to the present disclosure are not limited to the embodiments described above. Various modifications in design may be made freely in the specific structure of each part of the power conversion unit and the semiconductor device according to the present disclosure.

The present disclosure includes embodiments described in the following clauses.

Clause 1. A semiconductor device comprising:

a semiconductor element; a plurality of conductive connecting parts; a sealing part that covers the semiconductor element and a portion of each of the plurality of connecting parts; a plurality of signal terminals each of which is inserted into one of the plurality of connecting parts; and a holding part,

wherein the plurality of signal terminals protrude from the sealing part toward a first side in a thickness direction of the sealing part, and

the holding part covers a portion of each of the plurality of signal terminals.

Clause 2. The semiconductor device according to Clause 1, wherein each of the plurality of signal terminals include a base portion that extends in the thickness direction, and a protruding portion that protrudes beyond the base portion in a direction intersecting the thickness direction, and

the holding part covers the protruding portion and a portion of the base portion of each of the plurality of signal terminals.

Clause 3. A semiconductor module comprising:

the semiconductor device according to Clause 1 or 2; and

a control board disposed on the first side in the thickness direction with respect to the sealing part,

wherein the control board includes a plurality of through-holes extending in the thickness direction, and

each of the plurality of signal terminals extends through one of the plurality of through-holes.

Clause 4. The semiconductor module according to Clause 3, wherein the holding part is positioned between the sealing part and the control board in the thickness direction.

Clause 5. The semiconductor module according to Clause 4, wherein the holding part is in contact with the control board.

Clause 6. The semiconductor module according to Clause 4 or 5, wherein the holding part is in contact with the sealing part.

Clause 7. The semiconductor module according to any one of Clauses 3 to 6, wherein each of the plurality of signal terminals includes a base portion that extends in the thickness direction, and a first bulging portion that is enlarged relative to the base portion in a direction intersecting the thickness direction, and

the first bulging portion is press-fitted into the through-hole.

Clause 8. The semiconductor module according to any one of Clauses 3 to 7, wherein the control board includes a first surface facing the first side in the thickness direction, a second surface facing a second side in the thickness direction, and a first recess that is recessed from an inner surface of the through-hole and the second surface, and

the first recess includes a first portion that is inclined radially inward of the through-hole toward the first side in the thickness direction.

Clause 9. The semiconductor module according to any one of Clauses 3 to 8, wherein the sealing part includes a top surface facing the first side in the thickness direction, and a plurality of second recesses recessed from the top surface toward a second side in the thickness direction,

each of the plurality of second recesses overlaps with one of the plurality of connecting parts as viewed in the thickness direction, and

each of the plurality of second recesses includes a second portion that is inclined radially inward of the connecting part toward the second side in the thickness direction.

Clause 10. The semiconductor module according to any one of Clauses 3 to 9, wherein each of the plurality of signal terminals includes a base portion that extends in the thickness direction, and a second bulging portion that is enlarged relative to the base portion in a direction intersecting the thickness direction, and

the second bulging portion is press-fitted into the connecting part.

Clause 11. The semiconductor module according to any one of Clauses 3 to 10, wherein the semiconductor device further includes a supporting substrate that supports on which the semiconductor element and the plurality of connecting parts are mounted.

Clause 12. The semiconductor module according to Clause 11, wherein the semiconductor device further includes a power terminal that protrudes from the sealing part in a first direction perpendicular to the thickness direction,

the semiconductor element comprises a first element and a second element, and

the power terminal comprises a first power terminal electrically connected to the first element, and a second power terminal electrically connected to the second element.

Clause 13. The semiconductor module according to Clause 12, wherein the supporting substrate includes a first mounting section on which the first element is mounted and a second mounting section on which the second element is mounted,

the first mounting section is positioned on a first side in the first direction with respect to the second mounting section, and

the first power terminal and the second power terminal protrude from the sealing part toward the first side in the first direction.

Clause 14. The semiconductor module according to Clause 13, wherein the power terminal comprises a third power terminal electrically connected to the first element and the second element, and

the third power terminal protrudes from the sealing part toward a second side in the first direction.

Clause 15. The semiconductor module according to Clause 14, comprising a plurality of the semiconductor devices, wherein the plurality of semiconductor devices are arranged along a second direction perpendicular to the thickness direction and the first direction.

Clause 16. A power conversion unit comprising:

the semiconductor module according to Clause 15; and

a heat sink,

wherein the supporting substrate of each of the plurality of semiconductor devices includes a bottom surface facing a second side in the thickness direction,

in each of the plurality of semiconductor devices, the bottom surface is exposed from the sealing part, and

in each of the plurality of semiconductor devices, the bottom surface is in contact with the heat sink.

Clause 17. A method for manufacturing a semiconductor device, the semiconductor device including a semiconductor element, a plurality of conductive connecting parts, a sealing part covering the semiconductor element and a portion of each of the plurality of connecting parts, and a plurality of signal terminals protruding from the sealing part toward one side with respect to the sealing part,

the method comprising inserting the plurality of signal terminals into the plurality of connecting parts while collectively holding the plurality of signal terminals.

Clause 18. The method according to Clause 17, wherein the insertion of the plurality of connecting parts is performed while a portion of each of the plurality of signal terminals is covered and held by a holding part.

Clause 19. A vehicle comprising:

a drive source; and

the power conversion unit according to Clause 16,

wherein the plurality of semiconductor devices are electrically connected to the drive source.

What is claimed is:

1. A semiconductor device comprising:
a semiconductor element; a plurality of connecting parts each being conductive; a sealing part that covers the semiconductor element and a portion of each of the plurality of connecting parts; a plurality of signal terminals each inserted into one of the plurality of connecting parts; and a holding part,
wherein the plurality of signal terminals protrude from the sealing part toward a first side in a thickness direction of the sealing part, and
the holding part covers a portion of each of the plurality of signal terminals.

2. The semiconductor device according to claim 1, wherein each of the plurality of signal terminals include a base portion that extends in the thickness direction, and a protruding portion that protrudes beyond the base portion in a direction intersecting the thickness direction, and
the holding part covers the protruding portion and a portion of the base portion of each of the plurality of signal terminals.

3. A semiconductor module comprising:
the semiconductor device according to claim 1; and
a control board disposed on the first side in the thickness direction with respect to the sealing part,
wherein the control board includes a plurality of through-holes extending in the thickness direction, and
each of the plurality of signal terminals extends through one of the plurality of through-holes.

4. The semiconductor module according to claim 3, wherein the holding part is positioned between the sealing part and the control board in the thickness direction.

5. The semiconductor module according to claim 4, wherein the holding part is in contact with the control board.

6. The semiconductor module according to claim 4, wherein the holding part is in contact with the sealing part.

7. The semiconductor module according to claim 3, wherein each of the plurality of signal terminals includes a base portion that extends in the thickness direction, and a first bulging portion that is enlarged relative to the base portion in a direction intersecting the thickness direction, and
the first bulging portion is press-fitted into the through-hole.

8. The semiconductor module according to claim 3, wherein the control board includes a first surface facing the first side in the thickness direction, a second surface facing a second side in the thickness direction, and a first recess that is recessed from an inner surface of one of the plurality of through-holes and the second surface, and
the first recess includes a first portion that is inclined radially inward of the one of the plurality of through-holes toward the first side in the thickness direction.

9. The semiconductor module according to claim 3, wherein the sealing part includes a top surface facing the first side in the thickness direction, and a plurality of second recesses recessed from the top surface toward a second side in the thickness direction,
each of the plurality of second recesses overlaps with one of the plurality of connecting parts as viewed in the thickness direction, and
each of the plurality of second recesses includes a second portion that is inclined radially inward of the one of the plurality of connecting parts toward the second side in the thickness direction.

10. The semiconductor module according to claim 3, wherein each of the plurality of signal terminals includes a base portion that extends in the thickness direction, and a second bulging portion that is enlarged relative to the base portion in a direction intersecting the thickness direction, and
the second bulging portion is press-fitted into the connecting part.

11. The semiconductor module according to claim 3, wherein the semiconductor device further includes a supporting substrate that supports on which the semiconductor element and the plurality of connecting parts are mounted.

12. The semiconductor module according to claim 11, wherein the semiconductor device further includes a power terminal that protrudes from the sealing part in a first direction perpendicular to the thickness direction,
the semiconductor element comprises a first element and a second element, and
the power terminal comprises a first power terminal electrically connected to the first element, and a second power terminal electrically connected to the second element.

13. The semiconductor module according to claim 12, wherein the supporting substrate includes a first mounting section on which the first element is mounted and a second mounting section on which the second element is mounted,
the first mounting section is positioned on a first side in the first direction with respect to the second mounting section, and
the first power terminal and the second power terminal protrude from the sealing part toward the first side in the first direction.

14. The semiconductor module according to claim 13, wherein the power terminal comprises a third power terminal electrically connected to the first element and the second element, and
the third power terminal protrudes from the sealing part toward a second side in the first direction.

15. The semiconductor module according to claim 14, wherein a plurality of the semiconductor devices are provided, and the plurality of semiconductor devices are arranged along a second direction perpendicular to the thickness direction and the first direction.

16. A power conversion unit comprising:
the semiconductor module according to claim 15; and
a heat sink,
wherein the supporting substrate of each of the plurality of semiconductor devices includes a bottom surface facing a second side in the thickness direction,
in each of the plurality of semiconductor devices, the bottom surface is exposed from the sealing part, and
in each of the plurality of semiconductor devices, the bottom surface is in contact with the heat sink.

17. A method for manufacturing a semiconductor device including a semiconductor element, a plurality of connecting parts each being conductive, a sealing part covering the semiconductor element and a portion of each of the plurality of connecting parts, and a plurality of signal terminals protruding from the sealing part toward one side with respect to the sealing part,
the method comprising inserting the plurality of signal terminals into the plurality of connecting parts while collectively holding the plurality of signal terminals.

18. The method according to claim 17, wherein the insertion of the plurality of connecting parts is performed while a portion of each of the plurality of signal terminals is covered and held by a holding part.
